(19) United States
(12) Patent Application Publication
(10) Pub. No.: US 2026/0010075 A1
(43) Pub. Date: Jan. 8, 2026

(54) RESIST COMPOSITION AND PATTERN FORMING PROCESS

(71) Applicant: Shin-Etsu Chemical Co., Ltd., Tokyo (JP)

(72) Inventors: Shun Kikuchi, Joetsu-shi (JP); Masaki Ohashi, Joetsu-shi (JP); Satoshi Kusama, Joetsu-shi (JP); Kousuke Ohyama, Joetsu-shi (JP)

(73) Assignee: Shin-Etsu Chemical Co., Ltd., Tokyo (JP)

(21) Appl. No.: 19/254,137

(22) Filed: Jun. 30, 2025

(30) Foreign Application Priority Data
Jul. 5, 2024 (JP) 2024-109200

(51) Int. Cl. G03F 7/038; C08F 8/06; C08L 33/02; C08L 33/16; G03F 7/00; G03F 7/039; G03F 7/09; G03F 7/11

(52) U.S. Cl. CPC G03F 7/0388; C08F 8/06; C08L 33/02; C08L 33/16; G03F 7/039; G03F 7/094; G03F 7/11; G03F 7/70033

(57) ABSTRACT

The resist composition contains a polymer containing a repeat unit having a hypervalent iodine structure having the formula (1), a carboxy group-containing compound, and a solvent. The non-chemically amplified resist composition is excellent in sensitivity and maximum resolution in photolithography using high-energy radiation, such as electron beam (EB) lithography and EUV lithography.

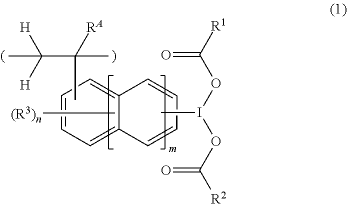

### CROSS-REFERENCE TO RELATED APPLICATION

This non-provisional application claims priority under 35 U.S.C. § 119(a) on Patent Application No. 2024-109200 filed in Japan on Jul. 5, 2024, the entire contents of which are hereby incorporated by reference.

### TECHNICAL FIELD

The present invention relates to a resist composition and a pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation extreme ultraviolet (EUV) lithography with a wavelength of 13.5 nm.

As the feature size is reduced, image blurs due to acid diffusion become a problem (see Non-Patent Document 1). To ensure resolution for fine patterns with a processing dimension of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. Therefore, it has been proposed to copolymerize a polymer with an acid generator in the form of an onium salt having a polymerizable olefin. With respect to the patterning of a resist film to a processing dimension of 16 nm et seq., it is believed impossible in the light of acid diffusion to form such a pattern from a chemically amplified resist composition. It would be desirable to have a non-chemically amplified resist composition.

A typical non-chemically amplified resist material is polymethyl methacrylate (PMMA). It is a positive resist material which increases solubility of organic solvent in developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV exposure is less than half the size by the ArF exposure. Therefore, the EUV exposure is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing iodine atoms. However, as mentioned above, the chemically amplified resist composition cannot reach the resolution desired in the EUV lithography where processing dimensions become smaller than ever. In particular, in a line-and-space pattern, as the pattern size decreases, the collapse and disconnection of the pattern remarkably increase, and thus reducing these leads to improvement of maximum resolution.

Patent Document 2 discloses a negative resist composition comprising a tin compound. Based on tin element having high EUV absorption, this resist composition is improved in stochastics and achieves high sensitivity and high resolution. Such so called metal resist compositions, however, suffer from many problems including low solubility in resist solvents, poor shelf stability, and defectiveness due to post-etching residues. Further, the metal resist compositions are of negative tone wherein the exposed region becomes a metal oxide which is insoluble in the developer. In their application to the patterning of contact holes, an additional reversal step is necessary, leaving an economical concern.

### CITATION LIST

Patent Document 1: JP-A 2018-5224
Patent Document 2: JP-A 2021-503482
Non-Patent Document 1: SPIE Vol. 5039 p1(2003)
Non-Patent Document 2: SPIE Vol. 6520 p65203L-1 (2007)

### SUMMARY OF THE INVENTION

The present invention has been made in view of the above circumstances, and an object thereof is to provide a non-chemically amplified resist composition excellent in sensitivity and maximum resolution in photolithography using high-energy radiation, particularly electron beam (EB) lithography and EUV lithography, and a pattern forming process using the same.

As a result of intensive studies to achieve the above object, the present inventors have found that a resist composition containing a polymer having a predetermined hypervalent iodine structure and a carboxy group-containing compound as principal components provides a resist film exhibiting excellent resolving power and is thus quite useful in precise micropatterning, and have completed the present invention.

That is, the present invention provides a resist composition and a pattern forming process described below.
1. A resist composition containing a polymer containing a repeat unit having a hypervalent iodine structure having the formula (1), a carboxy group-containing compound, and a solvent:

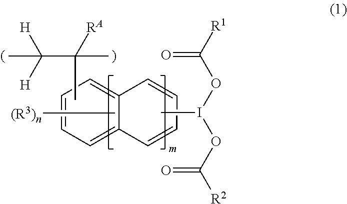

wherein m is 0 or 1, n is 0, 1, 2, 3, or 4 when m is 0, and is 0, 1, 2, 3, 4, 5, or 6 when m is 1,
   R^{A} is a hydrogen atom, halogen atom, methyl group, or trifluoromethyl group,
   R¹ and R² are each independently a halogen atom or a C₁-C₁₀ hydrocarbyl group which may contain a heteroatom, and R¹ and R² may bond together to form a ring with the carbon atoms to which they are attached and the intervenient atoms, and
   R³ is a halogen atom or a C₁-C₂₀ hydrocarbyl group which may contain a heteroatom.
2. The resist composition according to 1, wherein the carboxy group-containing compound is a polymer containing a repeat unit having the formula (2) or a compound having the formula (3):

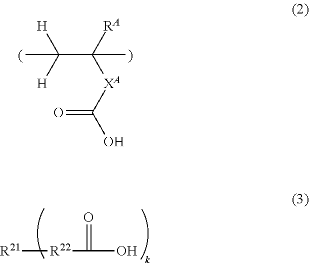

wherein R^{A} is a hydrogen atom, halogen atom, methyl group, or trifluoromethyl group,
   X^{A} is a single bond, phenylene group, naphthylene group, or *—C(═O)—O—X^{A1}—, wherein X^{A1} is a C₁-C₁₀ saturated hydrocarbylene group, phenylene group, or naphthylene group, the saturated hydrocarbylene group may contain a hydroxy group, ether bond, ester bond, or lactone ring, and * designates a valence bond to a carbon atom in a main chain,
   k is 1, 2, 3, or 4,
   R¹¹ is a C₁-C₄₀ k-valent hydrocarbon group or C₂-C₄₀ k-valent heterocyclic group, when k is 2, R¹¹ may be an ether bond, carbonyl group, azo group, thioether bond, carbonate bond, carbamate bond, sulfinyl group, or sulfonyl group, some or all of the hydrogen atoms in the k-valent hydrocarbon group or k-valent heterocyclic group may be substituted by a group containing a heteroatom, and some constituent —CH₂— in the k-valent hydrocarbon group may be substituted by a group containing a heteroatom, and
   R¹² is a single bond or a C₁-C₁₀ hydrocarbylene group, some or all of the hydrogen atoms in the hydrocarbylene group may be substituted by a group containing a heteroatom, some constituent —CH₂— in the hydrocarbylene group may be substituted by a group containing a heteroatom, and when k is 2, 3, or 4, a plurality of R¹² may be the same or different.
3. A laminate comprising a substrate and a resist film obtained from the resist composition according to 1 or 2 on the substrate.
4. The laminate according to 3, further comprising a lower layer film between the substrate and the resist film.
5. The laminate according to 3 or 4, wherein the resist film is formed by ligand exchange between the hypervalent iodine compound and the carboxy group-containing compound.
6. A pattern forming process comprising the steps of applying the resist composition according to 1 or 2 onto a substrate or a lower layer film of a substrate on which the lower layer film is laminated to form a resist film thereon, exposing the resist film to high-energy radiation, and developing the exposed resist film in a developer.

### Advantageous Effects of the Invention

The resist composition of the present invention exhibits both high sensitivity and resolution particularly in photolithography using i-line, KrF excimer laser light, ArF excimer laser light, EB, or EUV, and is quite useful in micropatterning.

### DESCRIPTION OF THE PREFERRED EMBODIMENT

### Resist Composition

A resist composition of the present invention contains a polymer having a predetermined hypervalent iodine structure (hereinafter, also referred to as a hypervalent iodine-containing polymer) and a carboxy group-containing compound as principal components.

### Hypervalent Iodine-Containing Polymer

The hypervalent iodine-containing polymer contains a repeat unit having a hypervalent iodine structure having the formula (1).

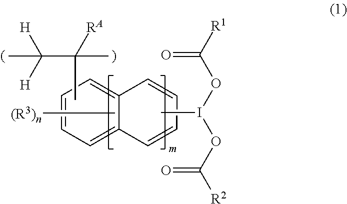

In the formula (1), m is 0 or 1. n is 0, 1, 2, 3, or 4 when m is 0, and is 0, 1, 2, 3, 4, 5, or 6 when m is 1.

In the formula (1), R^{A} is a hydrogen atom, halogen atom, methyl group, or trifluoromethyl group.

In the formula (1), R¹ and R² are each independently a halogen atom or a C₁-C₁₀ hydrocarbyl group which may contain a heteroatom. R¹ and R² may bond together to form a ring with the carbon atoms to which they are attached and the intervenient atoms.

Specific examples of the halogen atom of R¹ and R² include a fluorine atom, chlorine atom, bromine atom, and iodine atom.

The C₁-C₁₀ hydrocarbyl group of R¹ and R² may be saturated or unsaturated, and straight, branched, or cyclic. Specific examples thereof include C₁-C₁₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl; C₂-C₁₀ alkenyl groups such as vinyl and 2-propenyl; C₆-C₁₀ aryl groups such as phenyl and naphthyl; and combinations thereof.

Also included are hydrocarbyl groups in which some or all of the hydrogen atoms are substituted by a group containing a heteroatom such as oxygen, sulfur, nitrogen, or halogen, and some constituent —CH₂— is substituted by a group containing a heteroatom such as oxygen, sulfur, or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ and R² are preferably C₁-C₄ hydrocarbyl groups.

In the formula (1), R³ is halogen or a C₁-C₂₀ hydrocarbyl group which may contain a heteroatom.

Specific examples of the halogen of R³ include fluorine, chlorine, bromine, and iodine.

The hydrocarbyl group of R³ may be saturated or unsaturated, and straight, branched, or cyclic. Specific examples thereof include C₁-C₂₀ alkyl groups such as methyl, ethyl, n-propyl, isopropyl, n-butyl, isobutyl, sec-butyl, tert-butyl, n-pentyl, tert-pentyl, n-hexyl, n-octyl, 2-ethylhexyl, n-nonyl, and n-decyl; C₃-C₂₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl; C₂-C₂₀ alkenyl groups such as vinyl and 2-propenyl; C₆-C₂₀ aryl groups such as phenyl and naphthyl; and combinations thereof. Also included are hydrocarbyl groups in which some or all of the hydrogen atoms are substituted by a group containing a heteroatom such as oxygen, sulfur, nitrogen, or halogen, and some constituent —CH₂— is substituted by a group containing a heteroatom such as oxygen, sulfur, or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

Specific examples of the repeat unit having the formula (1) include, but are not limited to, those shown below. In the formulae, R^{A} is the same as described above.

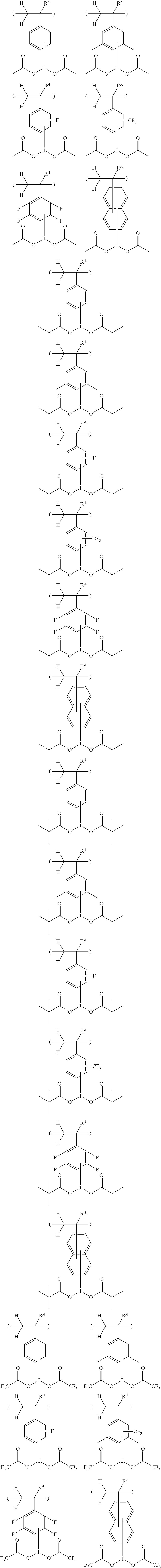

The hypervalent iodine-containing polymer may further contain a repeat unit other than the repeat unit having the formula (1) (hereinafter, also referred to as another repeat unit). Another repeat unit is not particularly limited, and a repeat unit is preferable that is capable of improving the solubility, in a solvent, of an insoluble polymer containing only a repeat unit having hypervalent iodine. Another repeat unit is preferably a repeat unit having a robust skeleton and a cyclic structure expected to have high etching resistance, or a repeat unit having a styrene skeleton as a principal component.

Specific examples of another repeat unit include, but are not limited to, those shown below. In the formulae, R^{A} is the same as described above, and X^{B} is each independently —CH₂— or —O—.

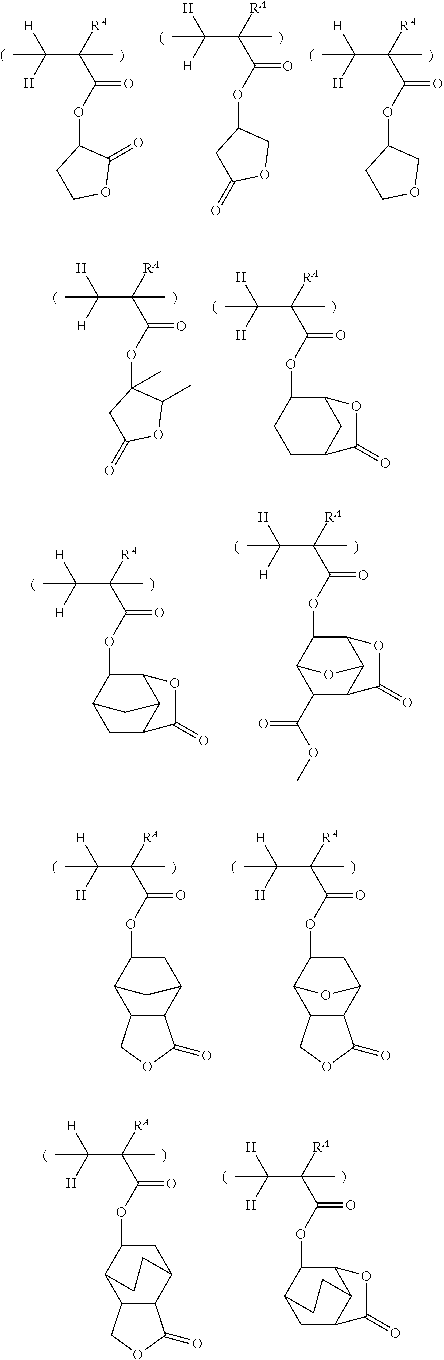

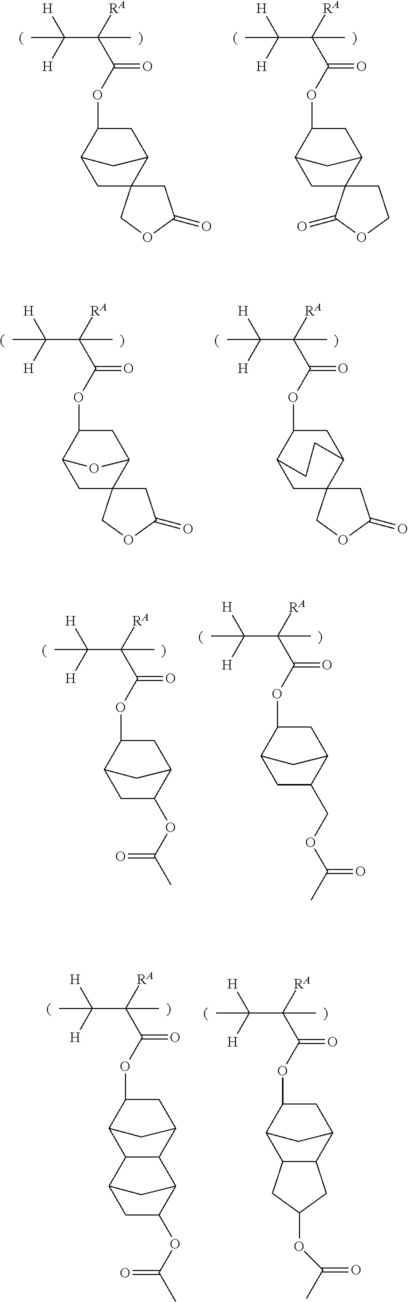

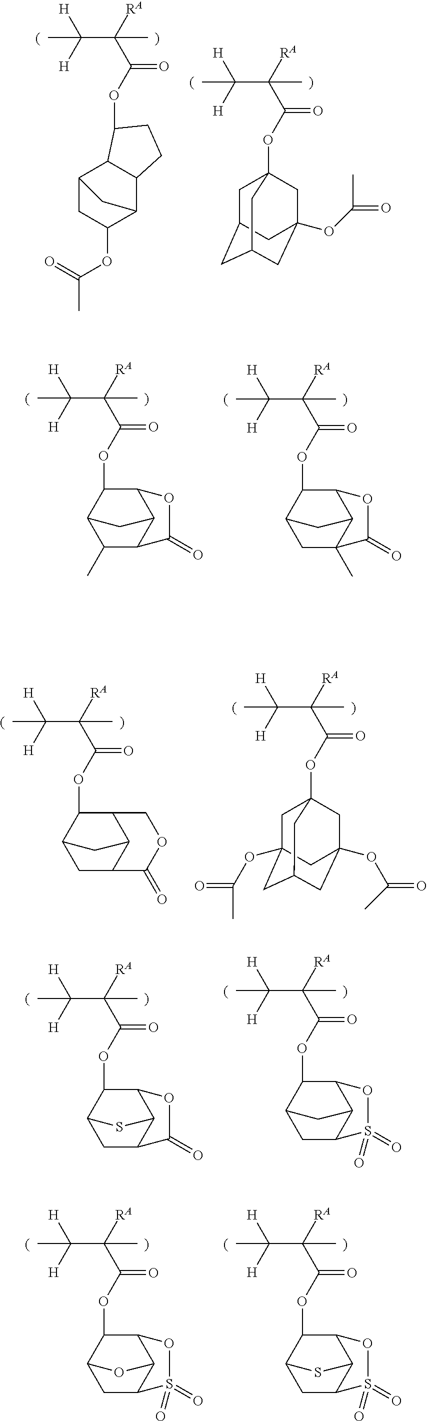

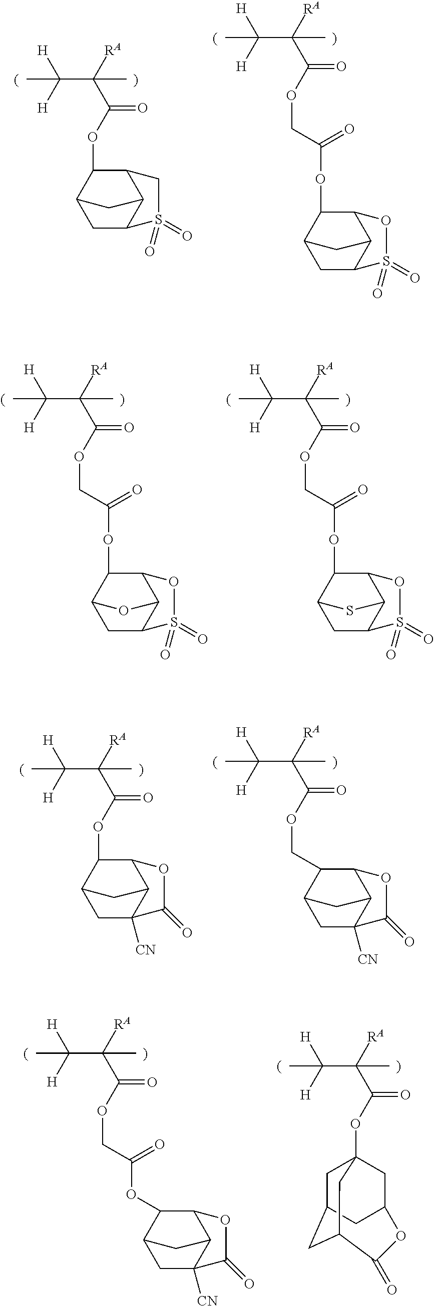

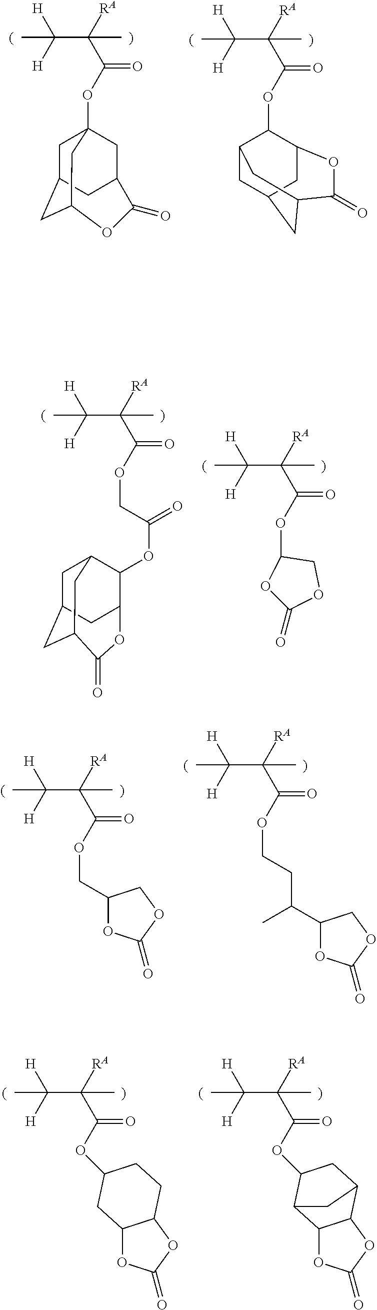

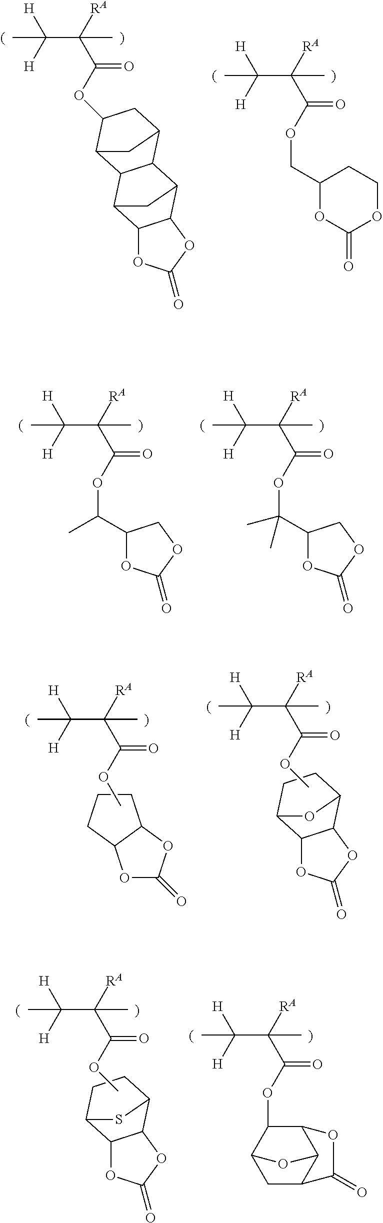

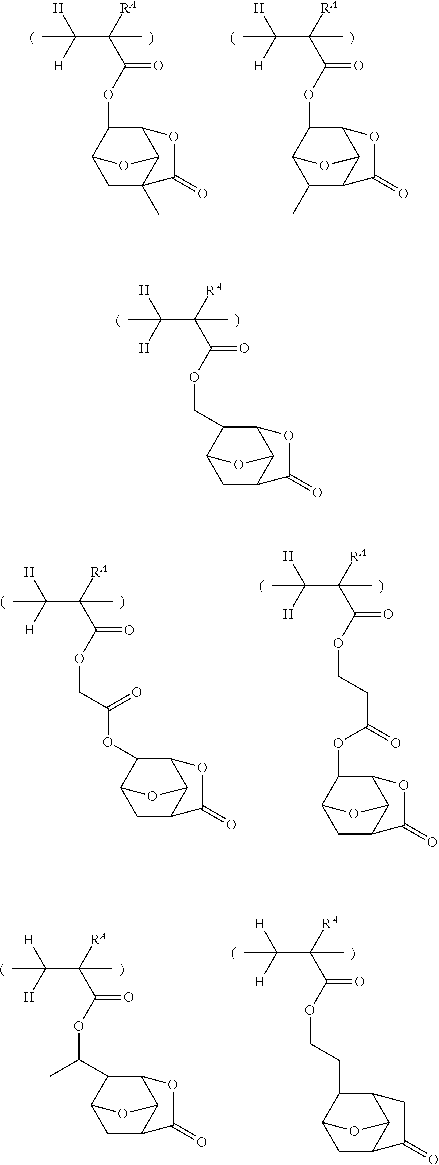

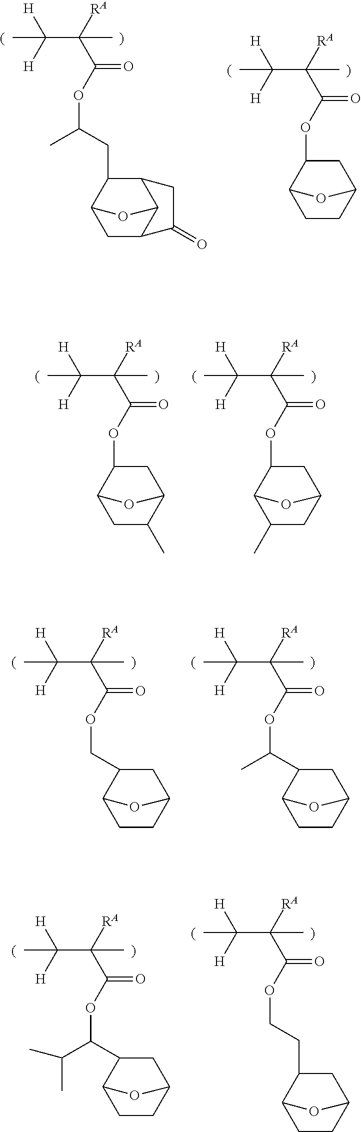

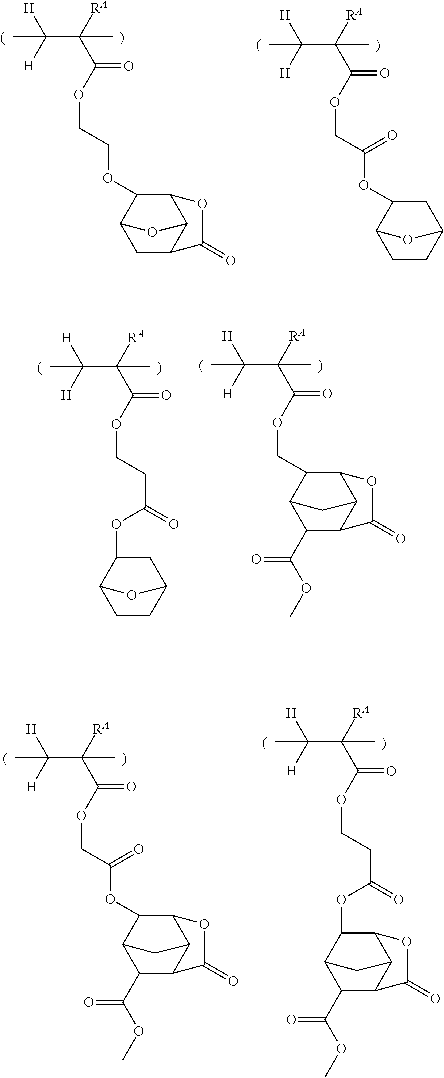

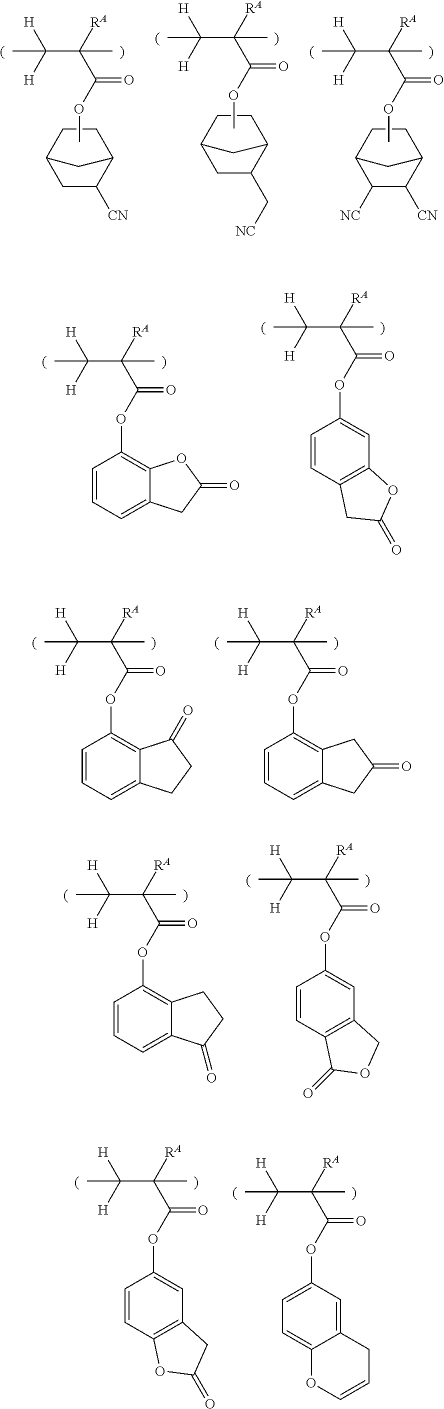

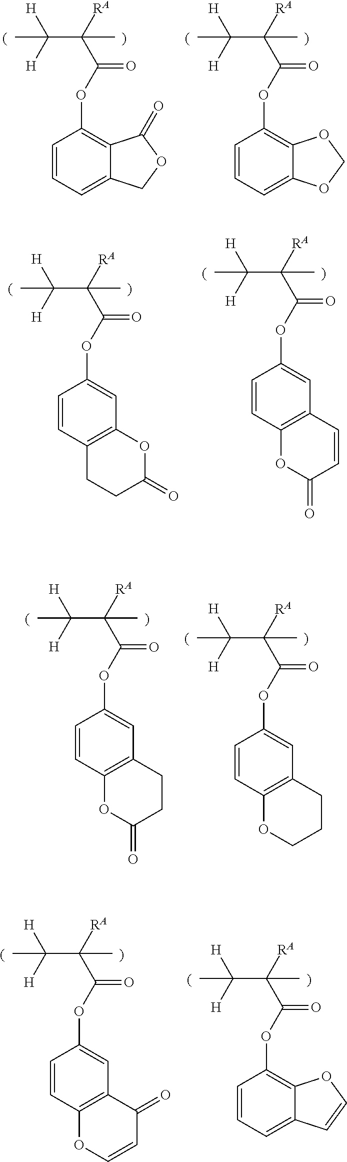

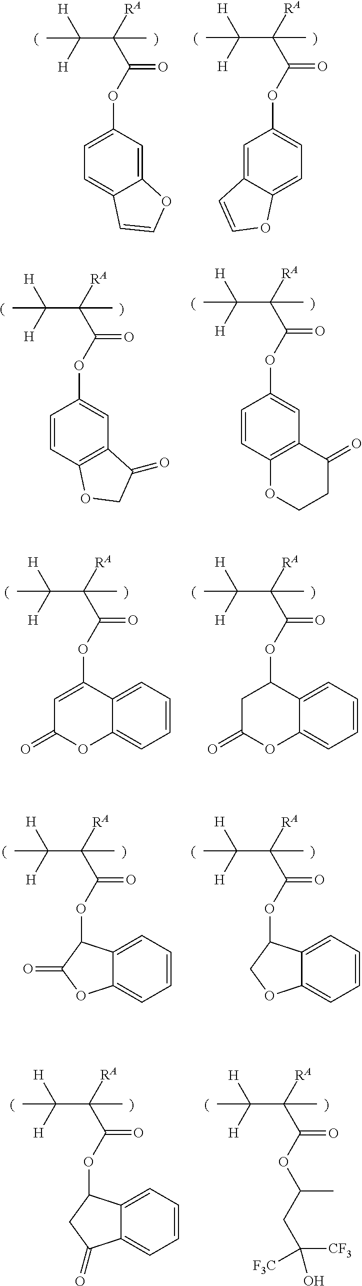

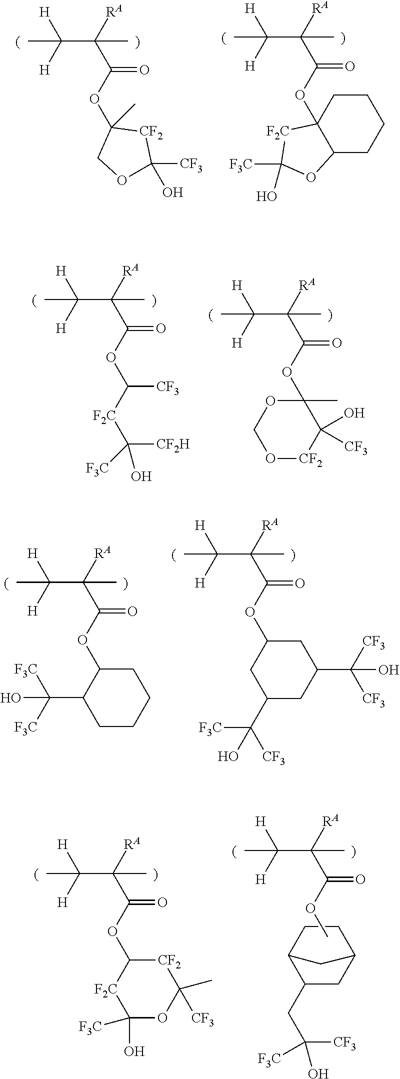

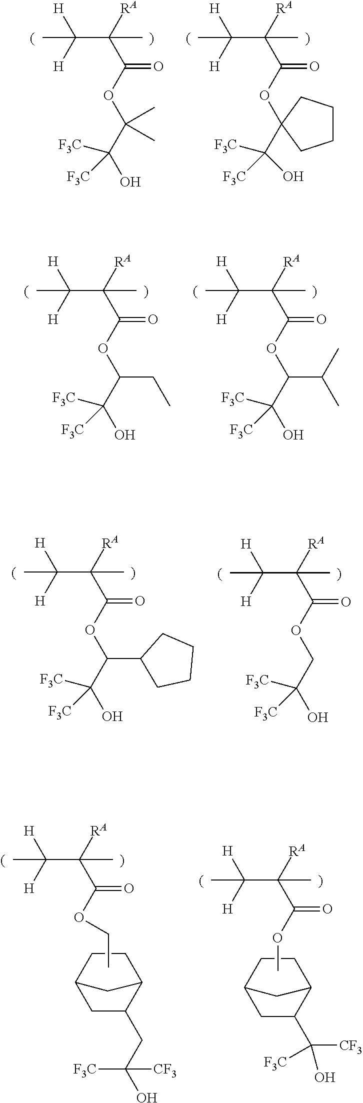

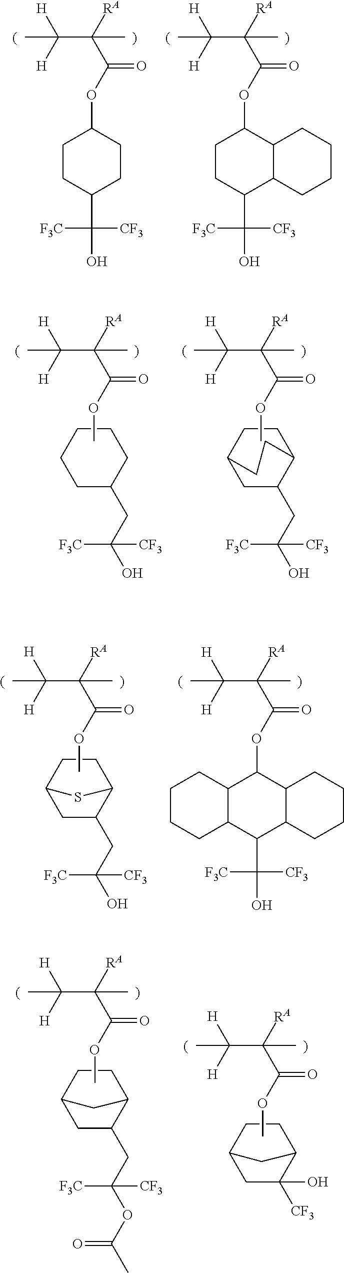

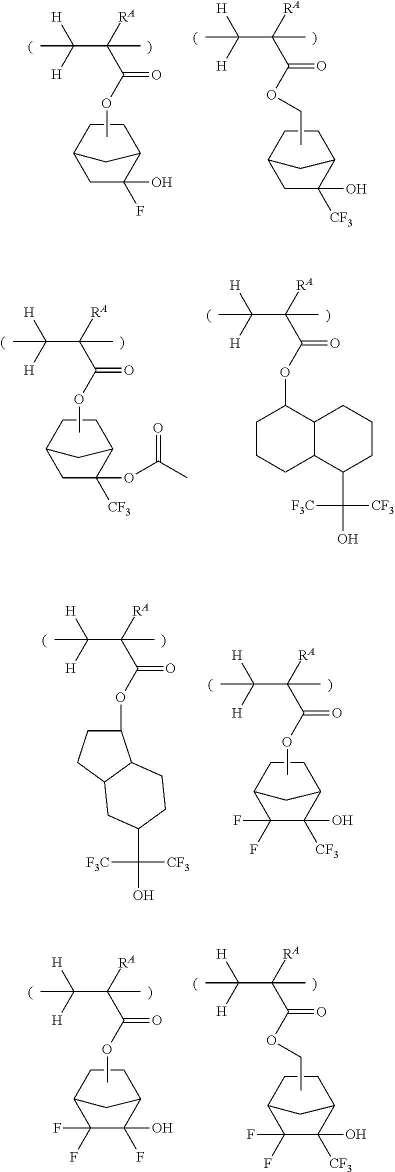

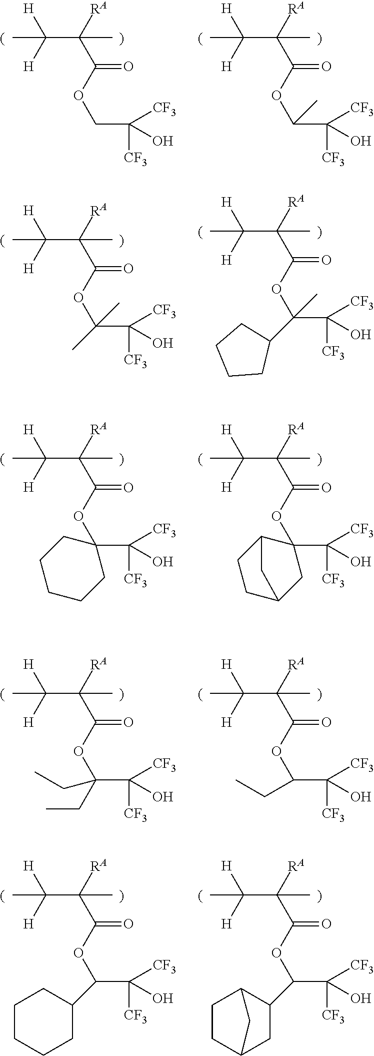

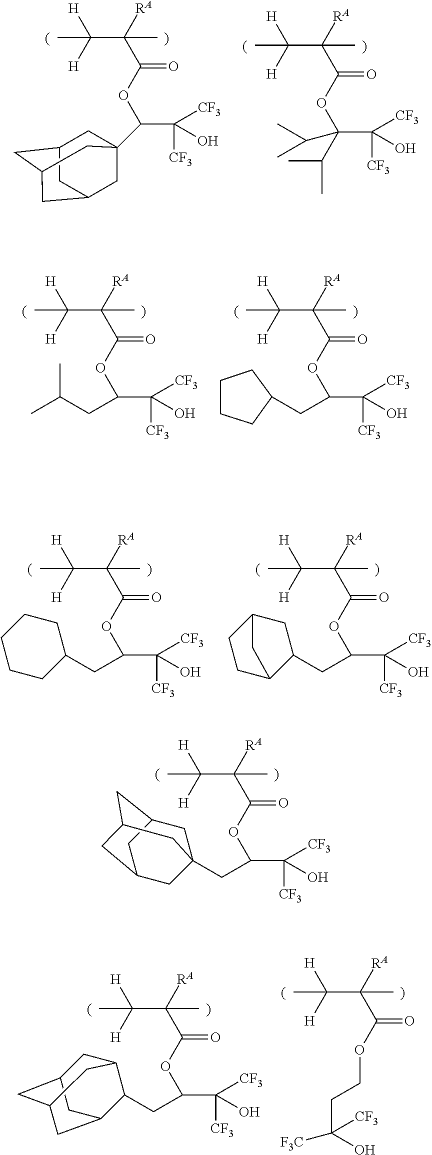

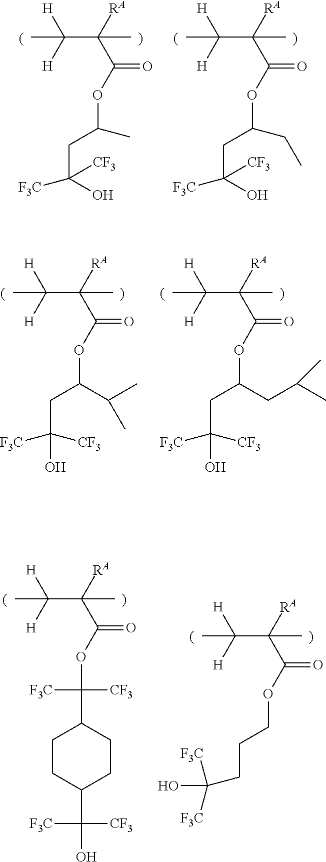

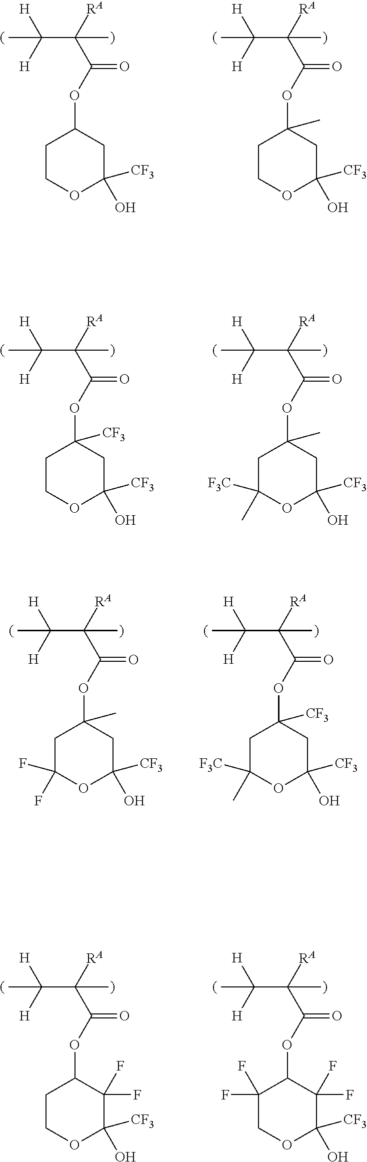

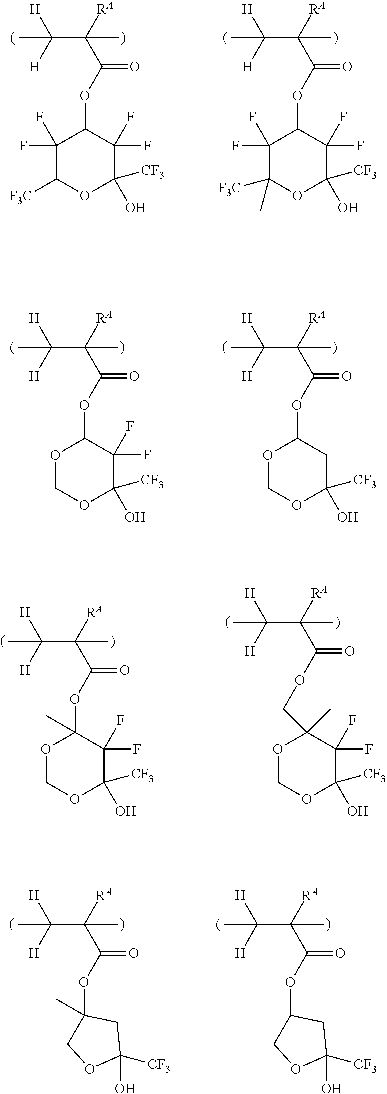

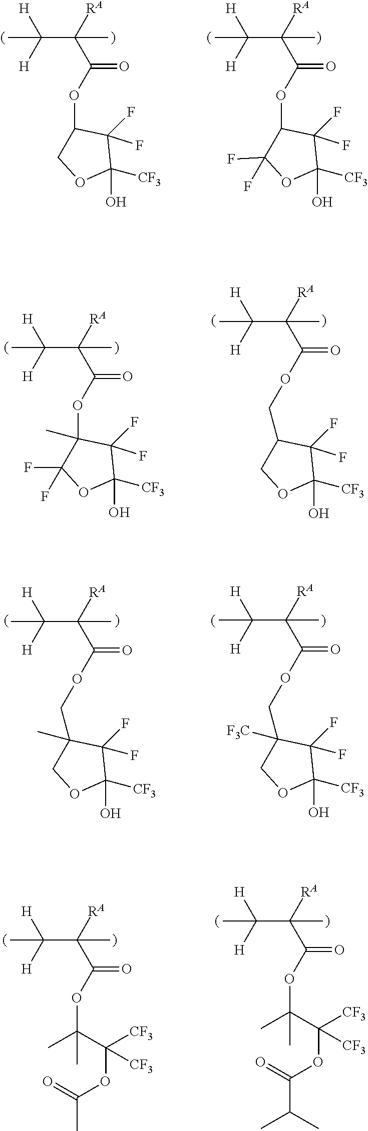

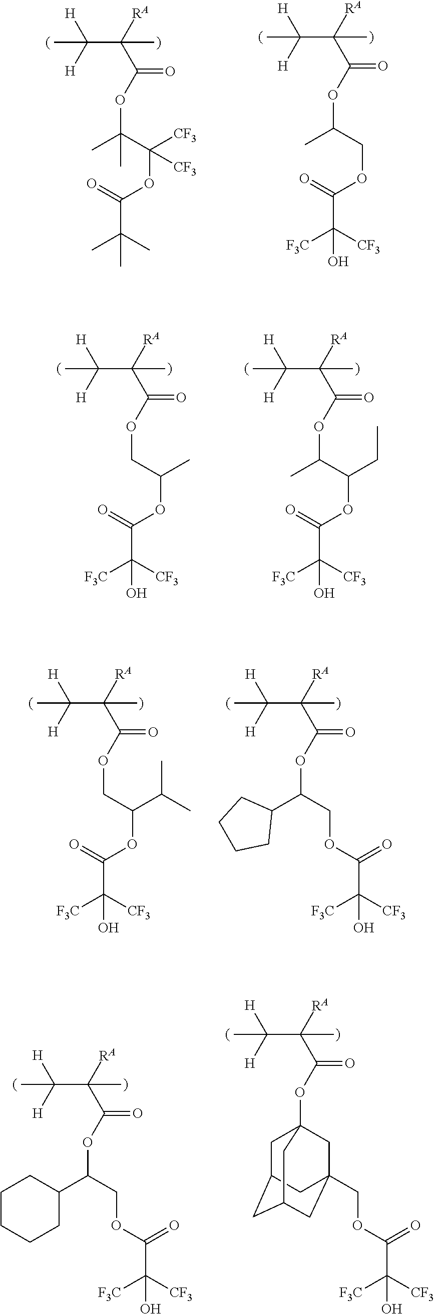

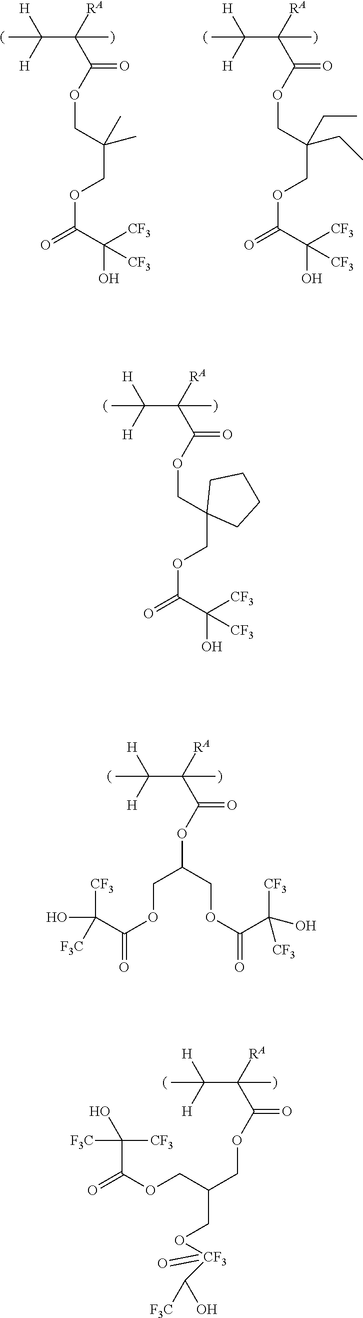

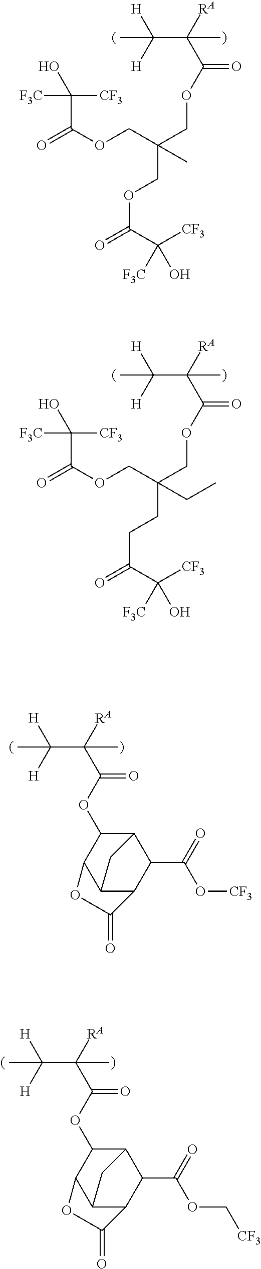

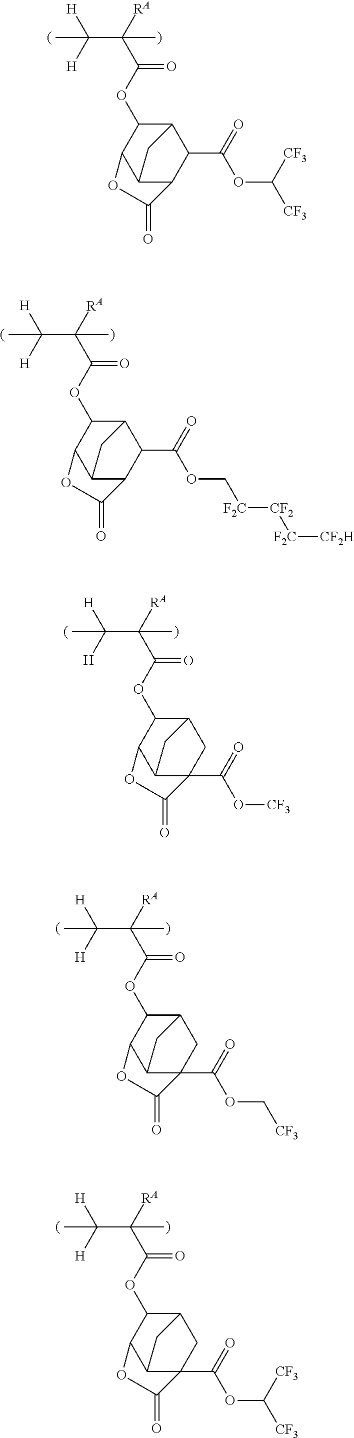

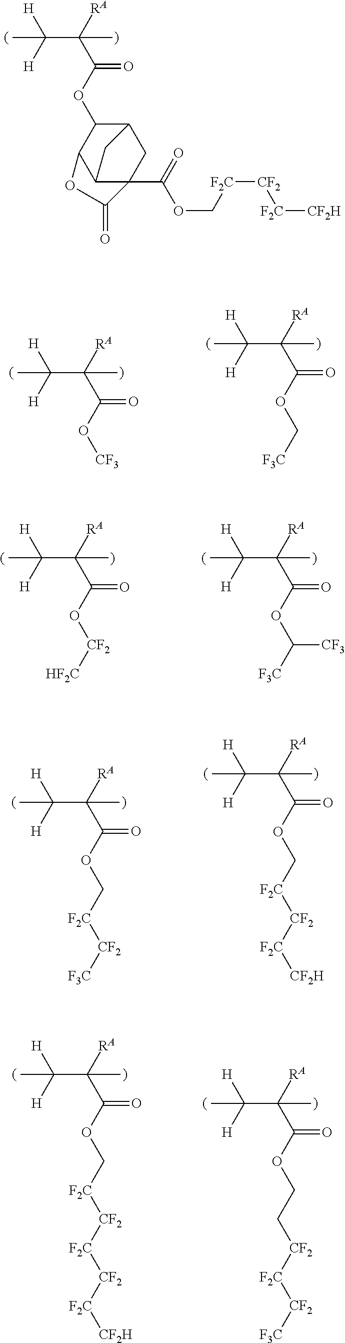

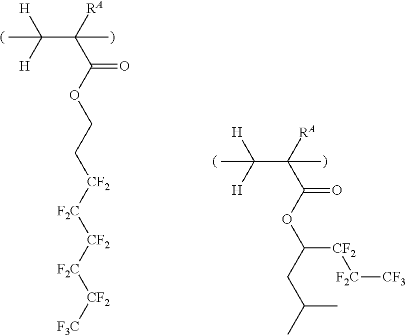

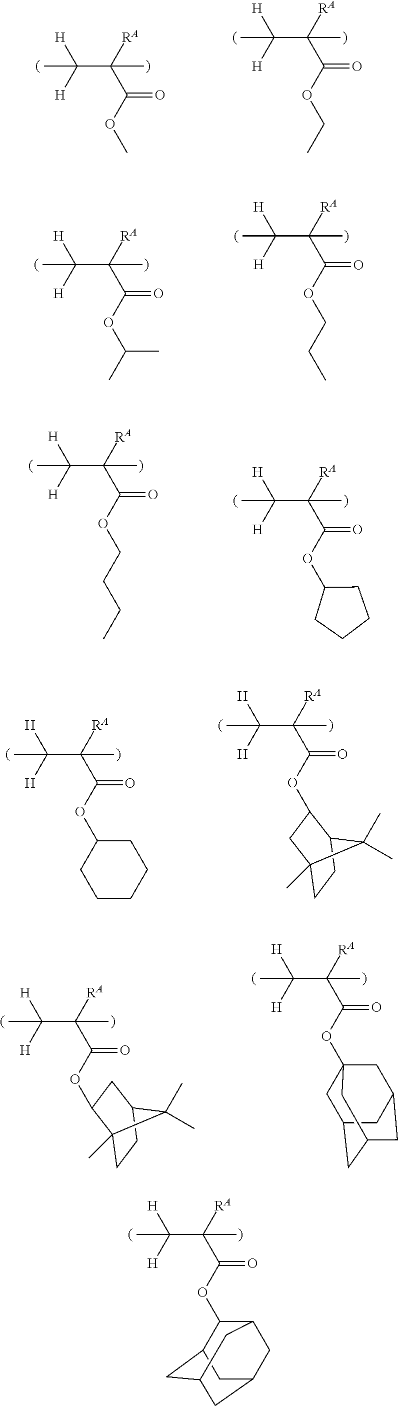

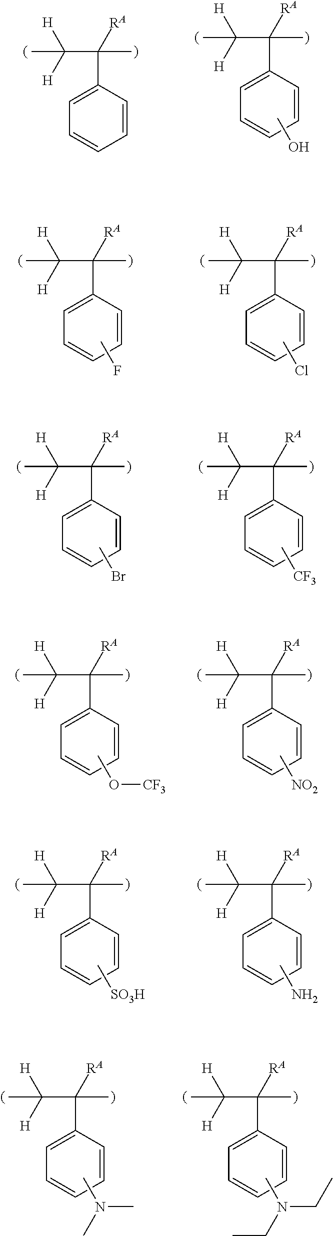

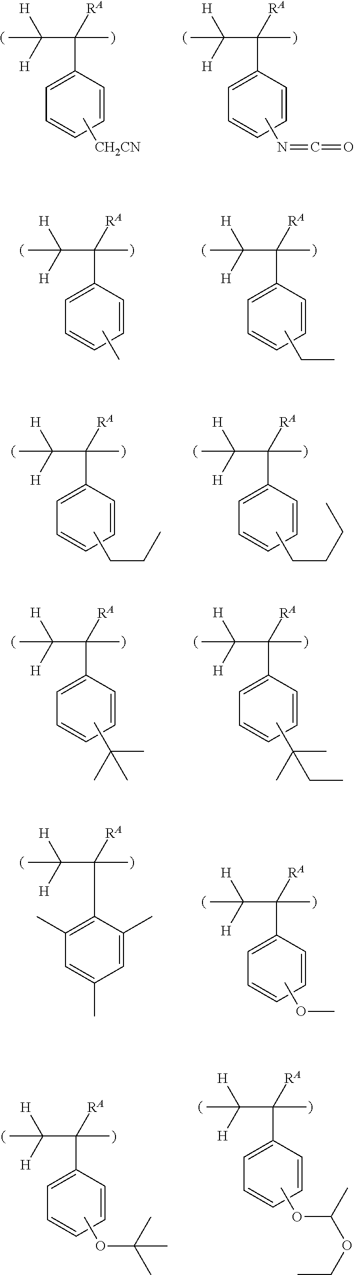

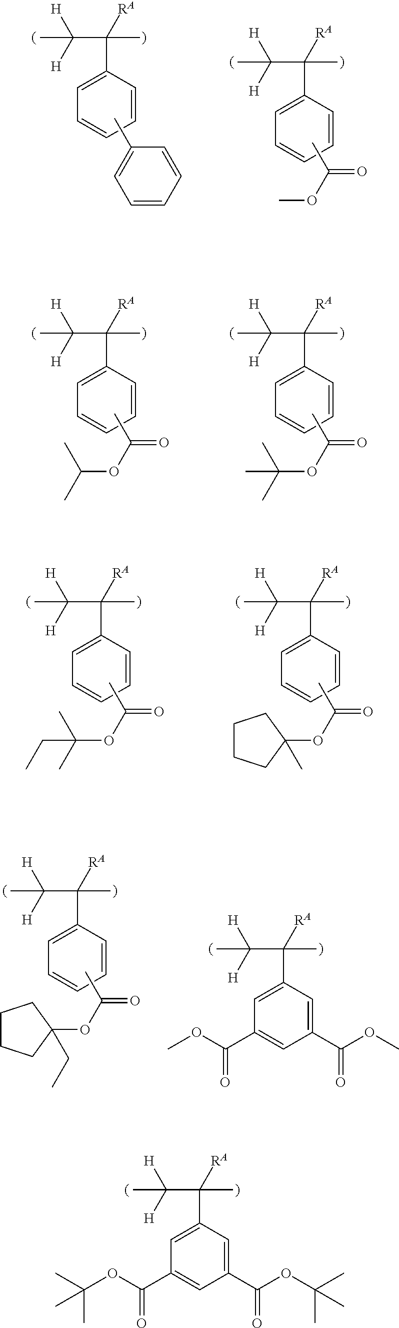

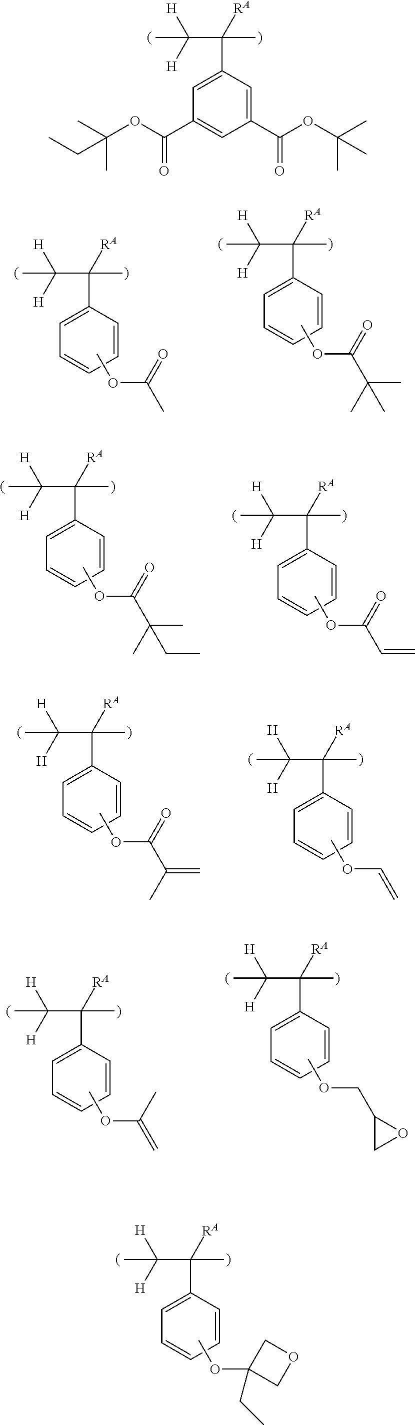

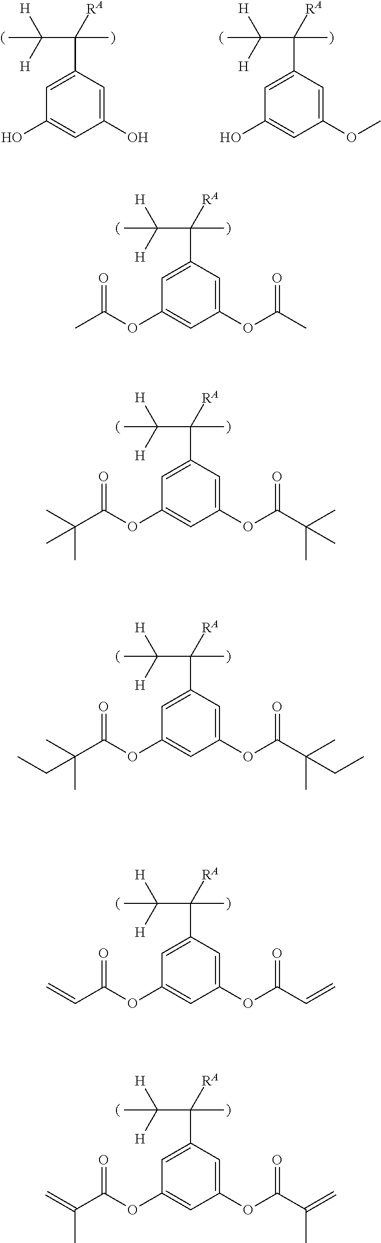

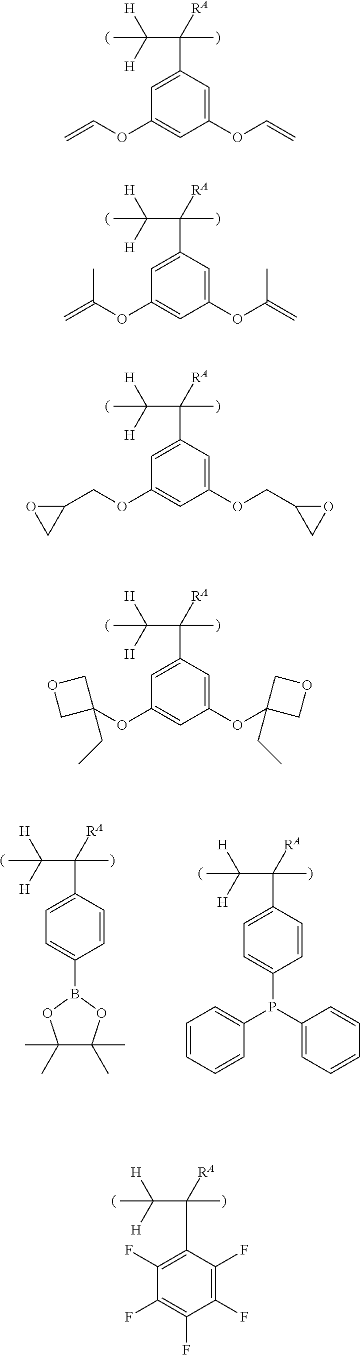

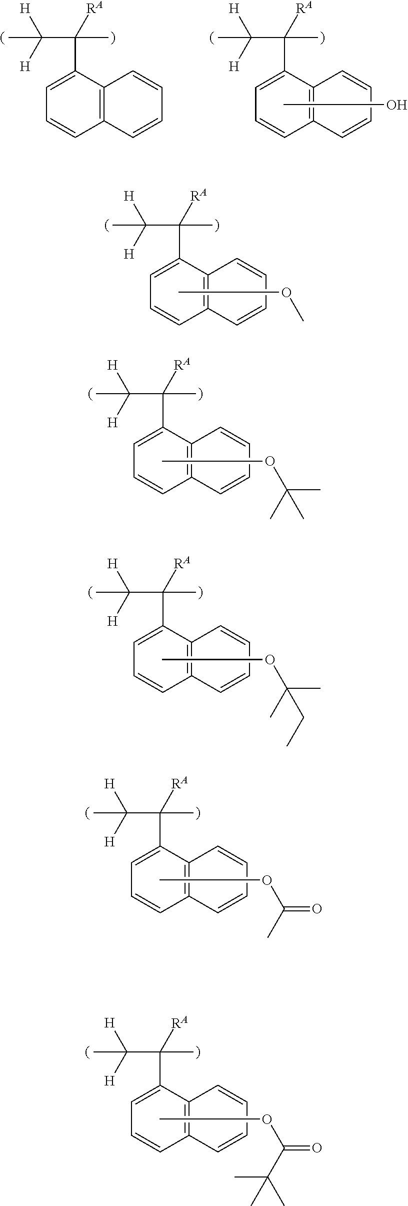

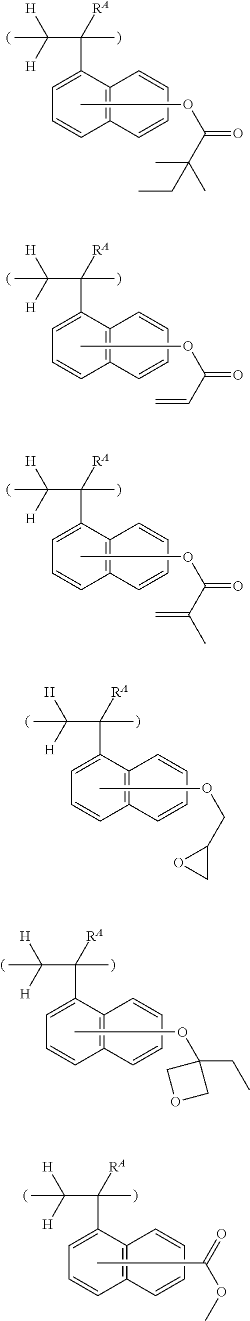

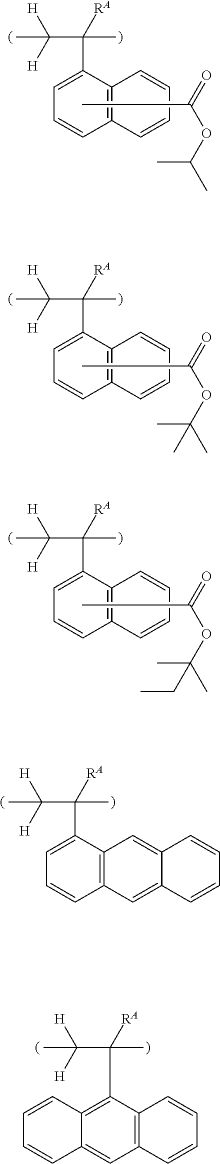

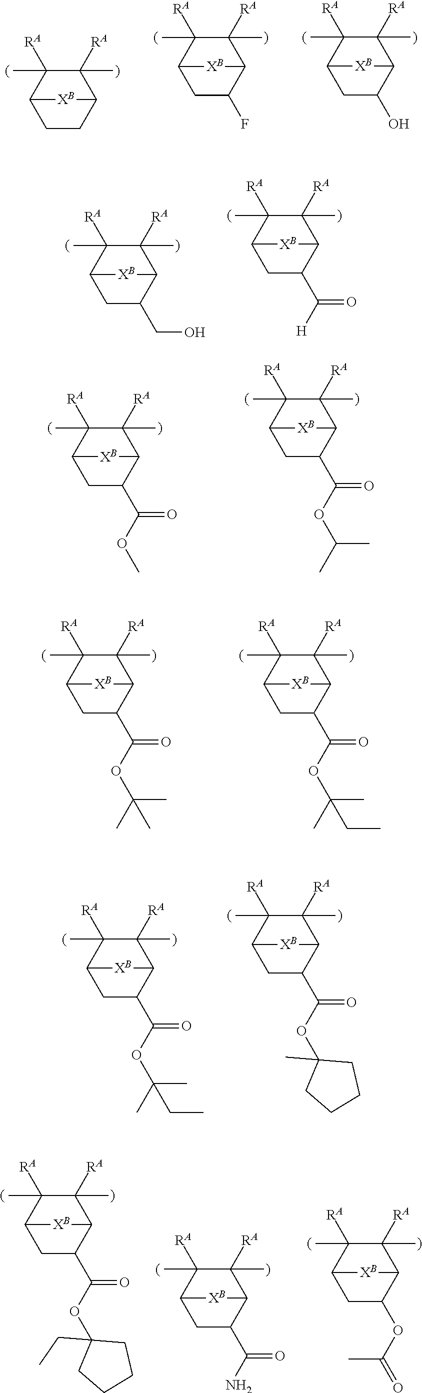

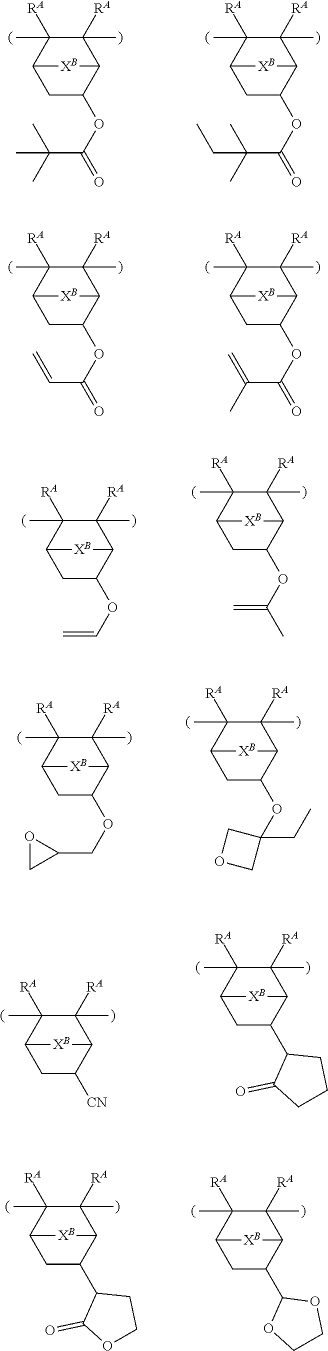

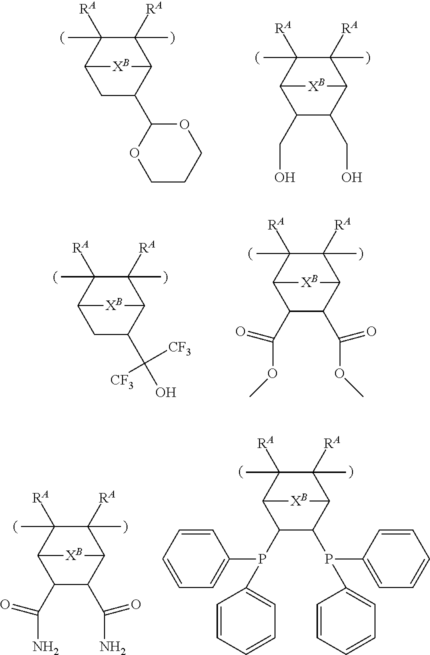

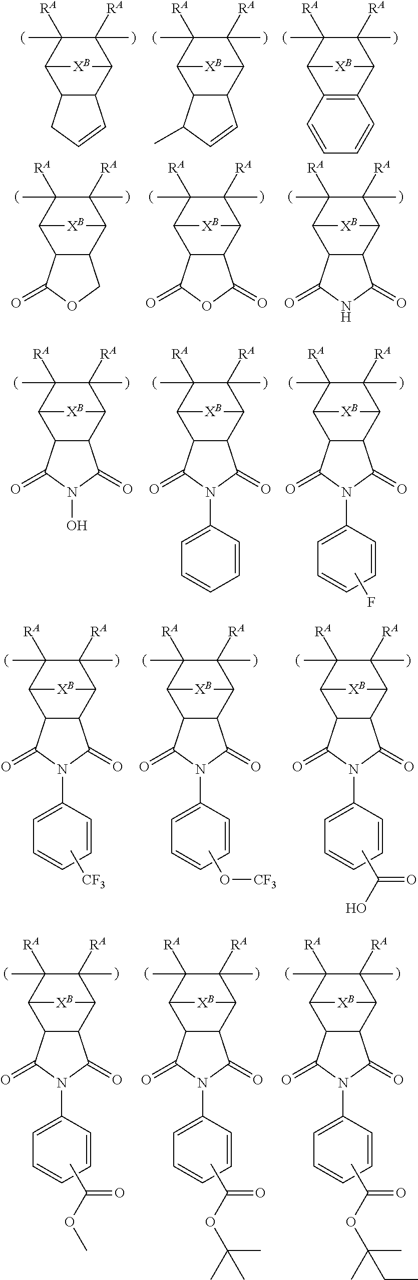

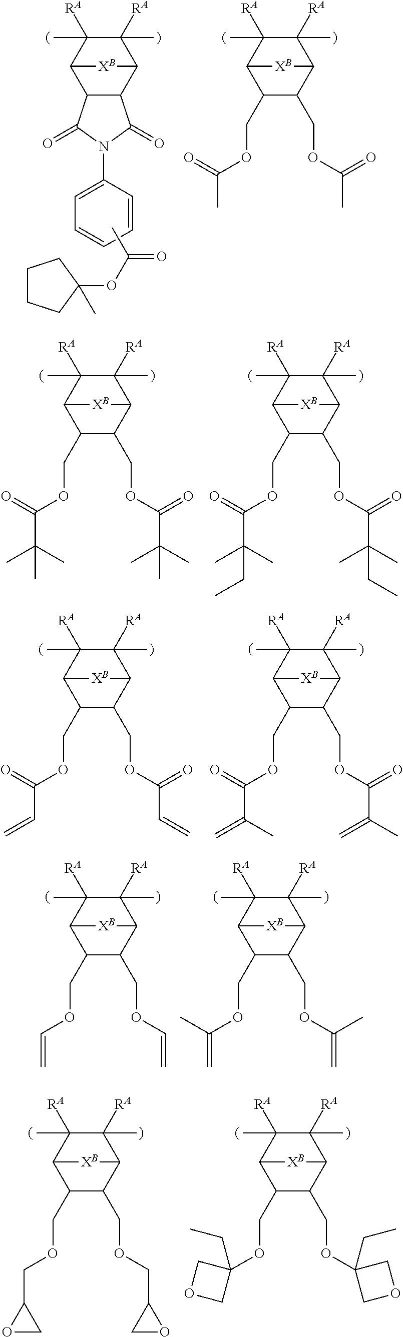

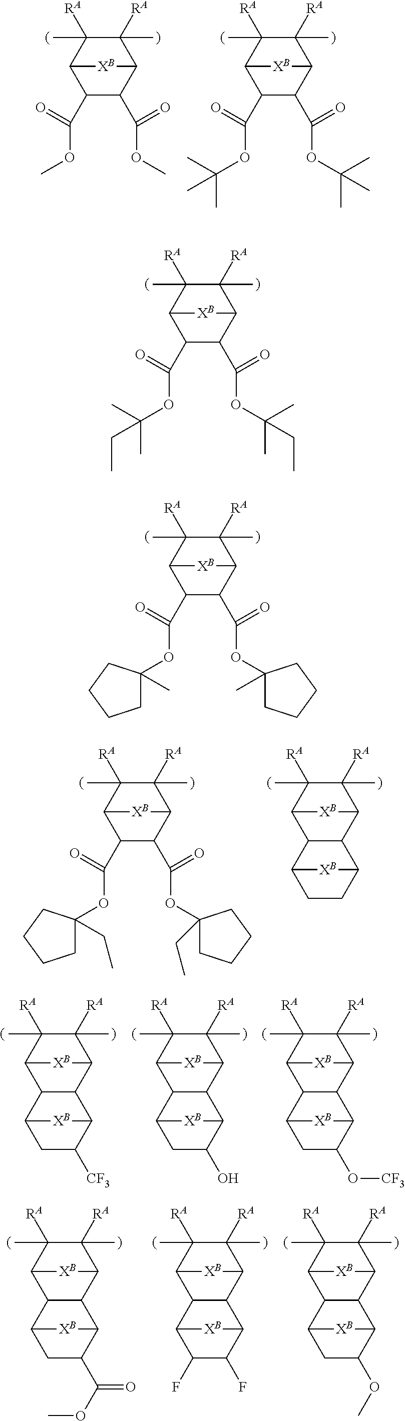

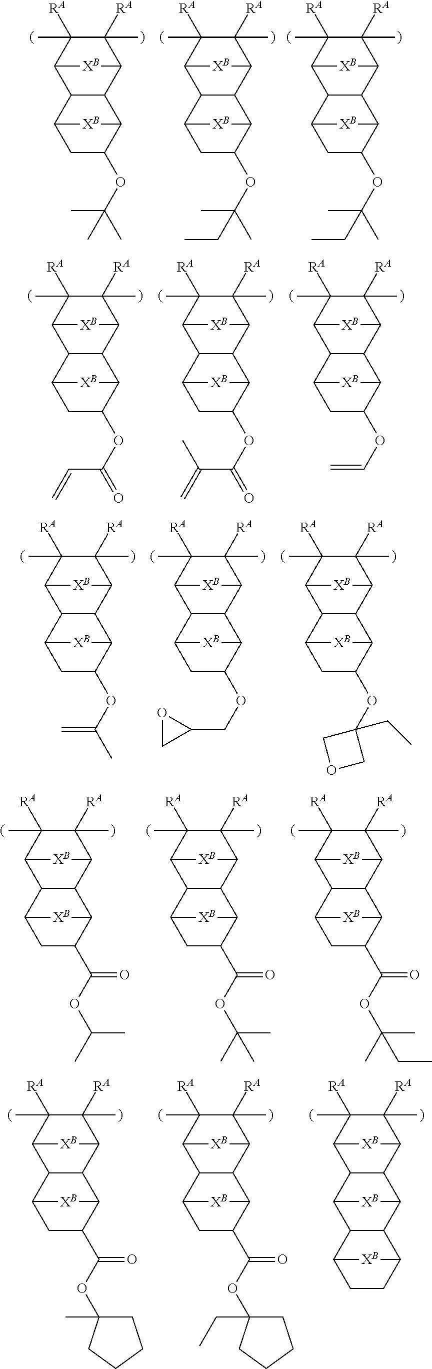

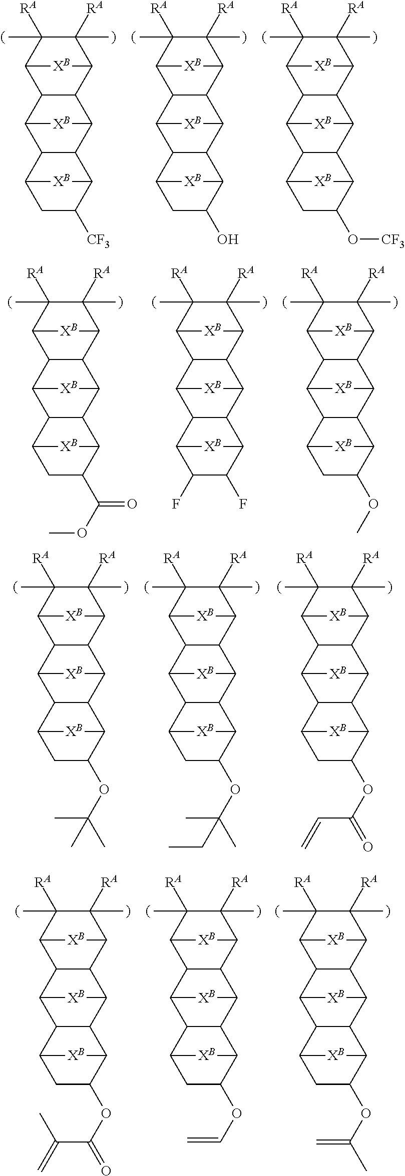

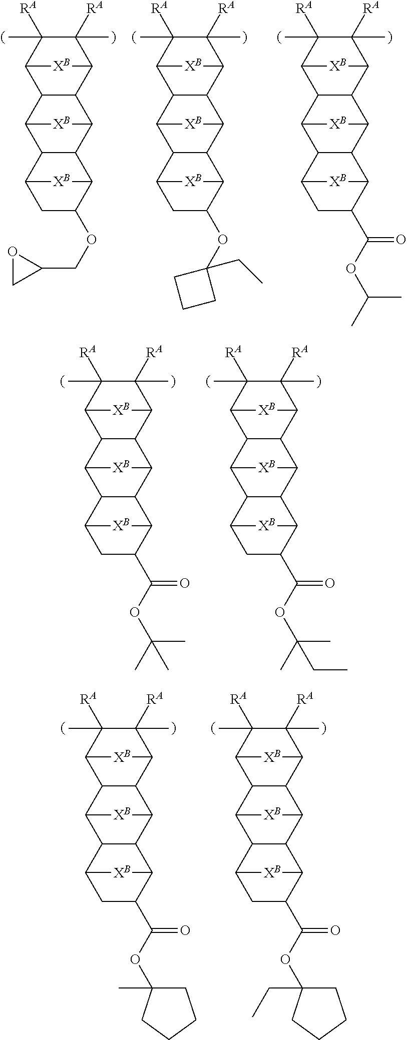

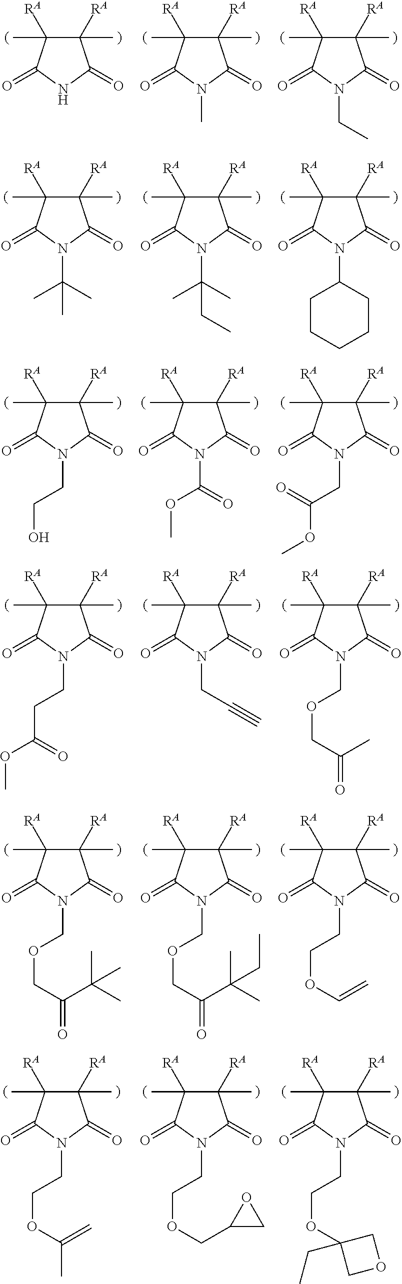

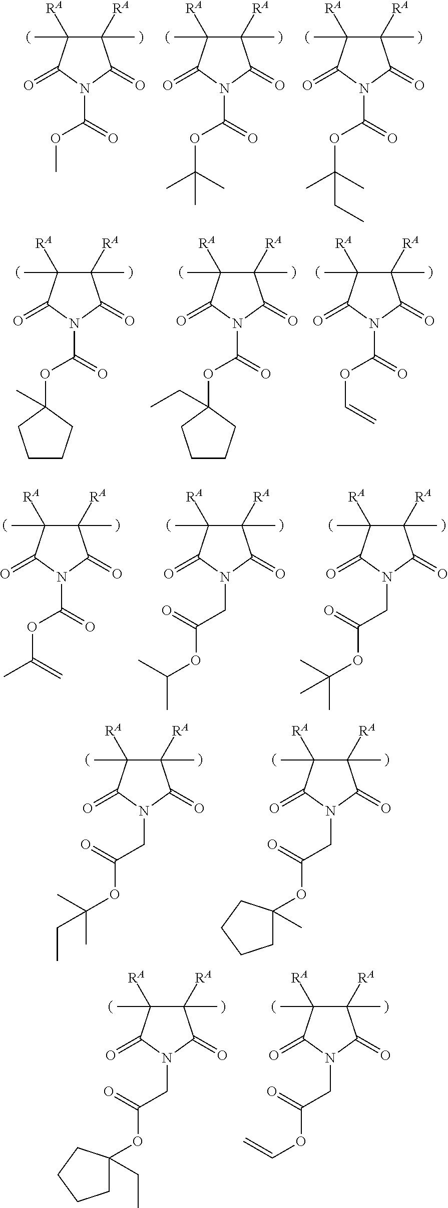

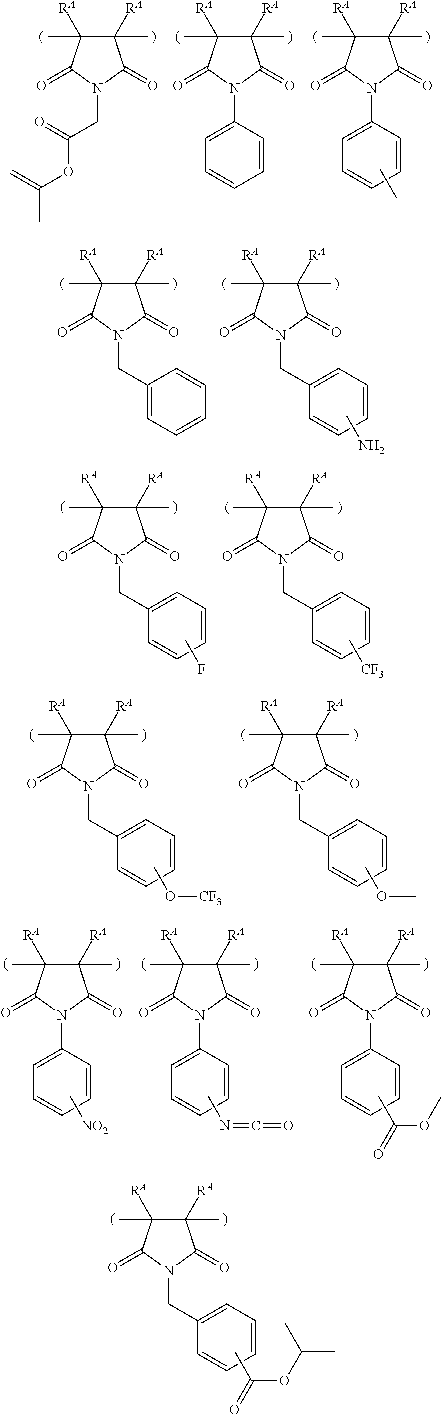

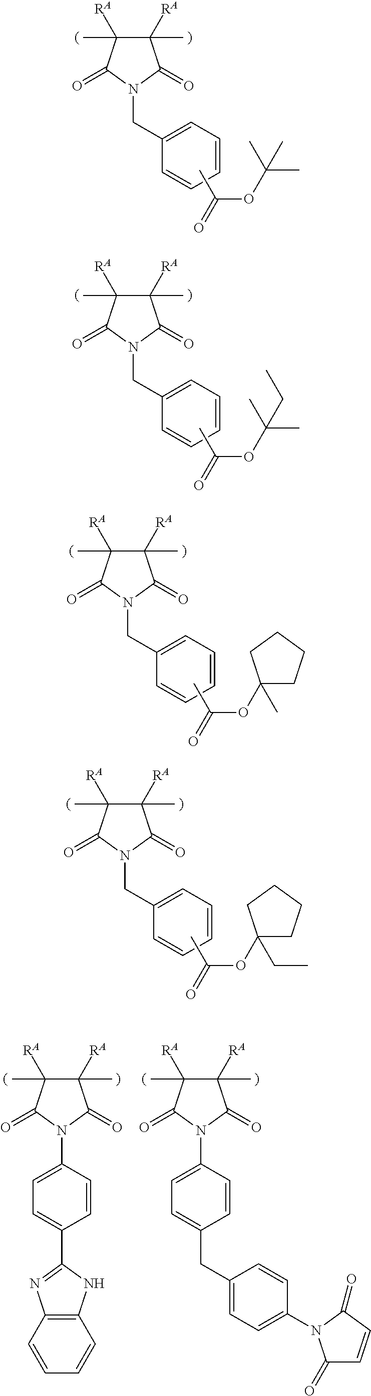

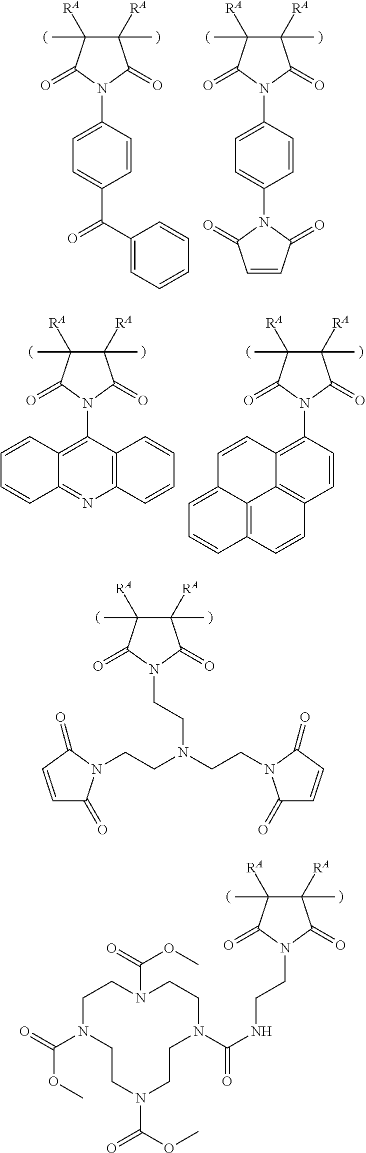

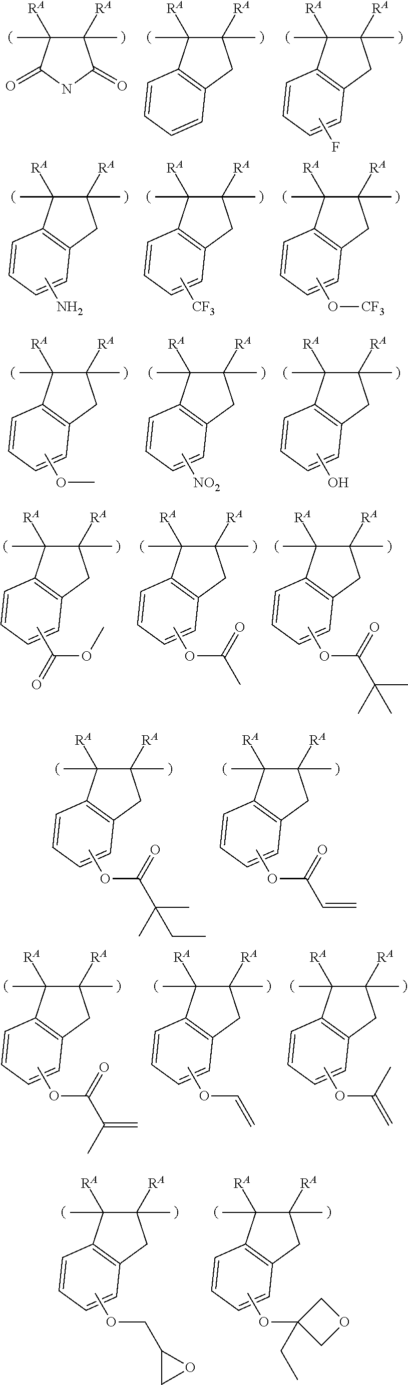

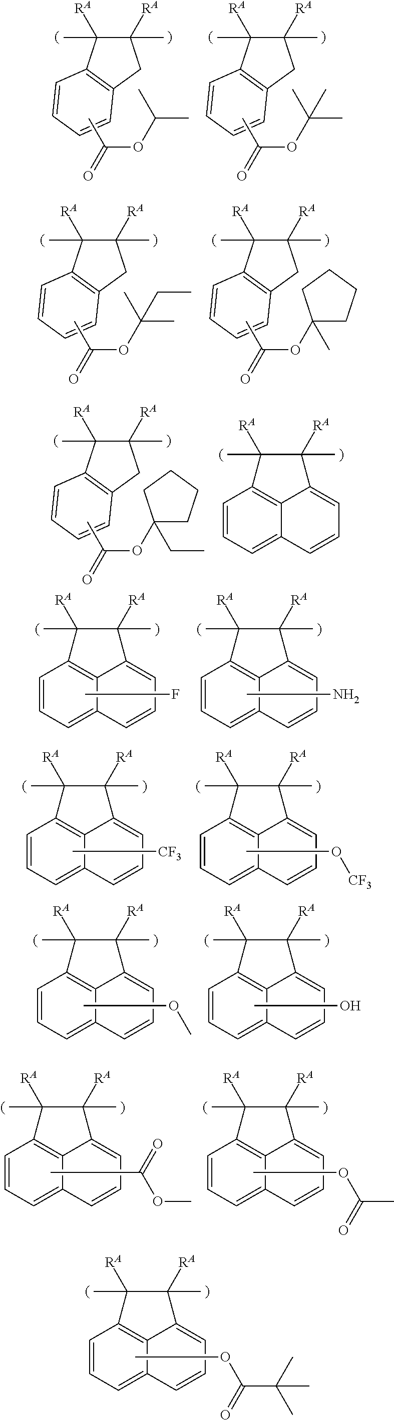

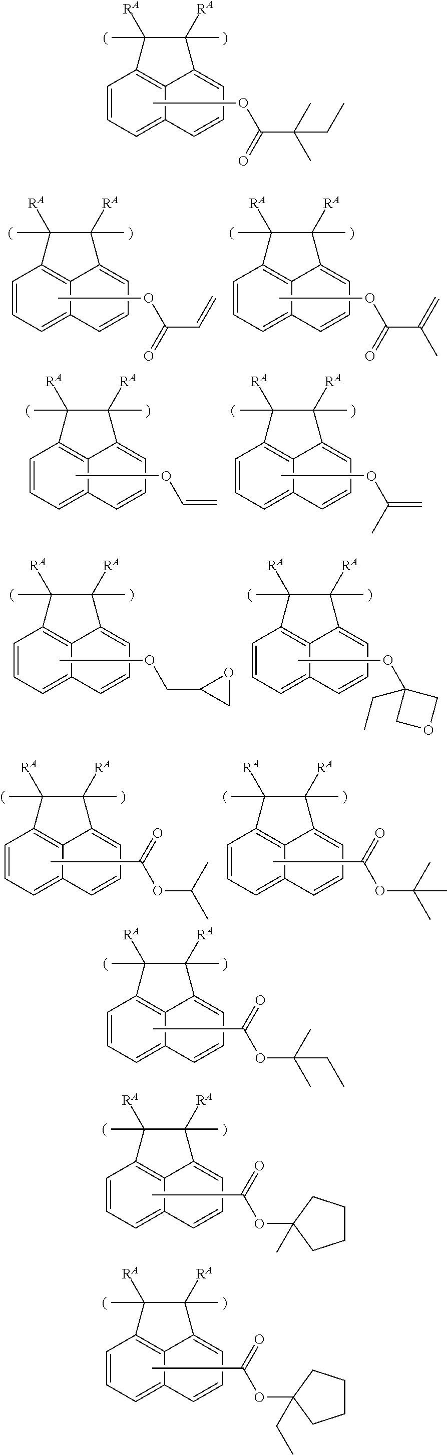

In the hypervalent iodine-containing polymer, the repeat unit having the formula (1) and another repeat unit are preferably present in a content ratio (molar ratio) of repeat unit having the formula (1):another repeat unit=10:90 to 90:10, more preferably 15:85 to 85:15, and still more preferably 20:80 to 80:20.

The hypervalent iodine-containing polymer preferably has a weight average molecular weight (Mw) of 1,000 to 500,000, and more preferably 3,000 to 100,000. In the present invention, Mw represents a value measured by gel permeation chromatography (GPC) versus polystyrene standards using tetrahydrofuran (THF) as a solvent.

If the hypervalent iodine-containing polymer has a wide molecular weight distribution (Mw/Mn), which indicates the presence of lower and higher molecular weight polymer fractions, there is a possibility that foreign matter is left on the pattern or the pattern profile is degraded after exposure. The influences of Mw and Mw/Mn become stronger as the pattern rule becomes finer. Therefore, the hypervalent iodine-containing polymer should preferably have a narrow dispersity (Mw/Mn) of 1.0 to 2.0 in order to provide a resist composition suitable for micropatterning to a small feature size.

Examples of the method of synthesizing the hypervalent iodine-containing polymer include a method in which an aryl iodide group-containing monomer is polymerized by adding a radical polymerization initiator in an organic solvent and heating, and then an iodine site is oxidized to form the hypervalent iodine-containing polymer.

Examples of the organic solvent used in the polymerization reaction include anisole, toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of such an initiator added is preferably 0.01 to 25 mol % per total amount of monomers to be polymerized. The reaction temperature is preferably 50 to 150° C., and more preferably 60 to 100° C. The reaction time is preferably 2 to 24 hours, and more preferably 2 to 12 hours from the viewpoint of production efficiency.

The polymerization initiator may be added to the monomer solution before supply to a reaction vessel, or an initiator solution may be prepared separately from the monomer solution and each solution may be supplied to a reaction vessel independently. Radicals generated from the initiator during waiting time may promote a polymerization reaction to generate an ultrahigh polymer. Therefore, from the viewpoint of quality control, each of the monomer solution and the initiator solution is preferably prepared and added dropwise independently. Further, a known chain transfer agent such as dodecyl mercaptan or 2-mercaptoethanol may be used in combination for adjusting the molecular weight. In this case, the amount of such a chain transfer agent added is preferably 0.01 to 20 mol % per total amount of monomers to be polymerized.

The amount of each monomer in the monomer solution is to be appropriately set, for example, so as to achieve the foregoing preferred content ratio of the repeat unit.

The hypervalent iodine-containing polymer may be used alone or in admixture of two or more having different composition ratios and different values of Mw and/or Mw/Mn.

### Carboxy Group-Containing Compound

The carboxy group-containing compound is preferably a polymer containing a repeat unit having the formula (2) or a compound having the formula (3).

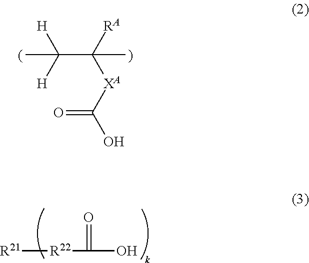

In the formula (2), R^{A} is a hydrogen atom, halogen atom, methyl group, or trifluoromethyl group. X^{A} is a single bond, phenylene group, naphthylene group, or *—C(═O)—O—X^{A1}—. X^{A1} is a C₁-C₁₀ saturated hydrocarbylene group, phenylene group, or naphthylene group, and the saturated hydrocarbylene group may contain a hydroxy group, ether bond, ester bond, or lactone ring. * designates a valence bond to a carbon atom in a main chain.

In the formula (3), k is 1, 2, 3, or 4.

In the formula (3), R¹¹ is a C₁-C₄₀ k-valent hydrocarbon group or C₂-C₄₀ k-valent heterocyclic group. When k is 2, R¹¹ may be an ether bond, carbonyl group, azo group, thioether bond, carbonate bond, carbamate bond, sulfinyl group or sulfonyl group. Some or all of the hydrogen atoms in the k-valent hydrocarbon group or k-valent heterocyclic group may be substituted by a group containing a heteroatom, and some constituent —CH₂-in the k-valent hydrocarbon group may be substituted by a group containing a heteroatom.

R¹² is a single bond or C₁-C₁₀ hydrocarbylene group, and some or all of the hydrogen atoms in the hydrocarbylene group may be substituted by a group containing a heteroatom, and some constituent —CH₂— in the hydrocarbylene group may be substituted by a group containing a heteroatom. When k is 2, 3, or 4, a plurality of R¹² may be the same or different.

The k-valent hydrocarbon group of R¹¹ may be saturated or unsaturated, and straight, branched, or cyclic. The k-valent hydrocarbon group is obtained by removing k number of hydrogen atoms from a hydrocarbon. Examples of the hydrocarbons include C₁-C₄₀ alkanes, C₂-C₄₀ alkenes, C₂-C₄₀ alkynes, C₃-C₄₀ cyclic saturated hydrocarbons, C₃-C₄₀ cyclic unsaturated hydrocarbons, and C₆-C₄₀ aromatic hydrocarbons.

Examples of the C₁-C₄₀ alkanes include methane, ethane, propane, butane, pentane, hexane, heptane, octane, nonane, decane, and structural isomers thereof.

Examples of the C₁-C₄₀ alkenes include ethylene, propylene, butene, pentene, hexene, heptene, octene, nonene, decene, and structural isomers thereof.

Examples of the C₁-C₄₀ alkynes include acetylene, propyne, butyne, pentyne, hexyne, heptyne, octyne, nonyne, decyne, and structural isomers thereof.

Examples of the C₃-C₄₀ cyclic saturated hydrocarbons include cyclopropane, cyclobutane, cyclohexane, cycloheptane, cyclooctane, adamantane, and norbornane.

Examples of the C₃-C₄₀ cyclic unsaturated hydrocarbons include cyclopropene, cyclobutene, cyclopentene, cyclohexene, cycloheptene, cyclooctene, and norbornene.

Examples of the C₆-C₄₀ aromatic hydrocarbons include benzene, naphthalene, and biphenyl.

The k-valent heterocyclic group of R¹¹ is obtained by removing k number of hydrogen atoms from a heterocyclic compound. Examples of the heterocyclic compound include furane, pyridine, pyrazole, and thiazolidine.

In the k-valent hydrocarbon group and k-valent heterocyclic group, some or all of the hydrogen atoms may be substituted by a group containing a heteroatom such as oxygen, sulfur, nitrogen or halogen, so that the group may contain hydroxy, cyano, fluorine, chlorine, bromine, or iodine. In the k-valent hydrocarbon group, some constituent —CH₂— may be substituted by a group containing a heteroatom such as oxygen, sulfur or nitrogen, so that the group may contain carbonyl, ether bond, thioether bond, ester bond, sulfonic ester bond, carbonate bond, carbamate bond, lactone ring, sultone ring, or carboxylic anhydride (—C(═O)—O—C(═O)—).

The hydrocarbylene group of R¹¹ may be saturated or unsaturated, and straight, branched, or cyclic. Specific examples thereof include C₁-C₂₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, and decane-1,10-diyl, undecane-1,11-diyl, and dodecane-1,12-diyl; C₃-C₁₀ cyclic saturated hydrocarbylene groups such as cyclopentanediyl, cyclohexanediyl, norbornanediyl, and adamantanediyl; C₂-C₂₀ unsaturated aliphatic hydrocarbylene groups such as vinylene and propene-1,3-diyl; C₆-C₂₀ arylene groups such as phenylene and naphthylene; and combinations thereof. In the hydrocarbylene group, some or all of the hydrogen atoms may be substituted by a group containing a heteroatom such as oxygen, sulfur, nitrogen or halogen, and some constituent —CH₂— may be substituted by a group containing a heteroatom such as oxygen, sulfur or nitrogen, so that the group may contain hydroxy, cyano, fluorine, chlorine, bromine, iodine, carbonyl, ether bond, thioether bond, ester bond, sulfonic ester bond, carbonate bond, carbamate bond, lactone ring, sultone ring, or carboxylic anhydride.

In the carboxy group-containing compounds having the formula (3), k is preferably 2, 3 or 4. In this case, those compounds having the formula (3) are preferred because when mixed with the hypervalent iodine compound, they form a high molecular weight, robust resist film having etching resistance and developer resistance.

Specific examples of the carboxy group-containing repeat unit having the formula (2) include, but are not limited to, those shown below. In the formulae, R^{A} is the same as described above.

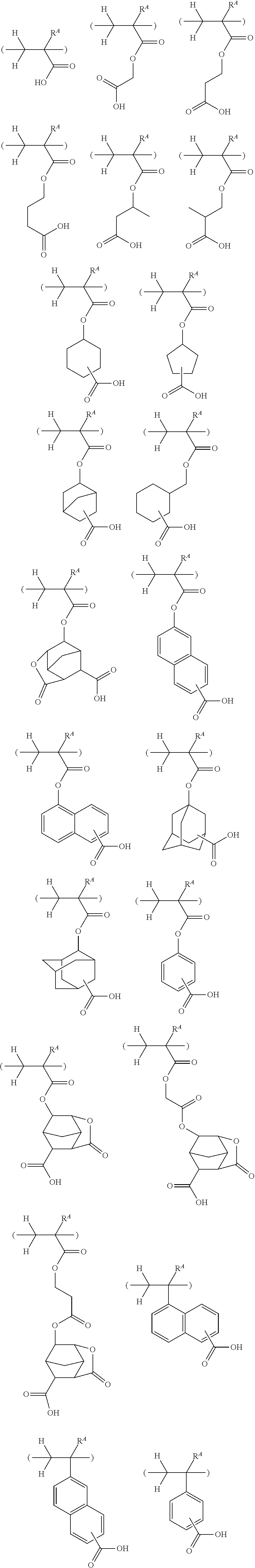

Specific examples of the carboxy group-containing repeat unit having the formula (3) include, but are not limited to, those shown below.

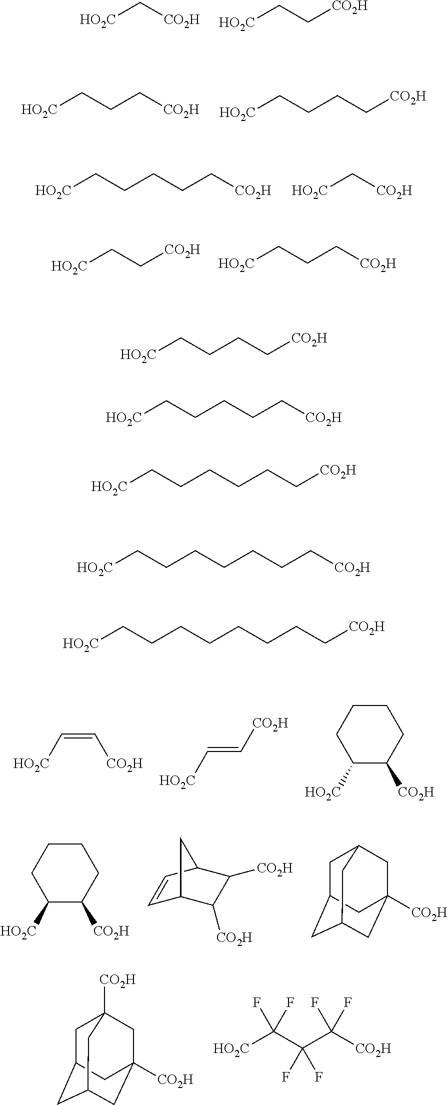

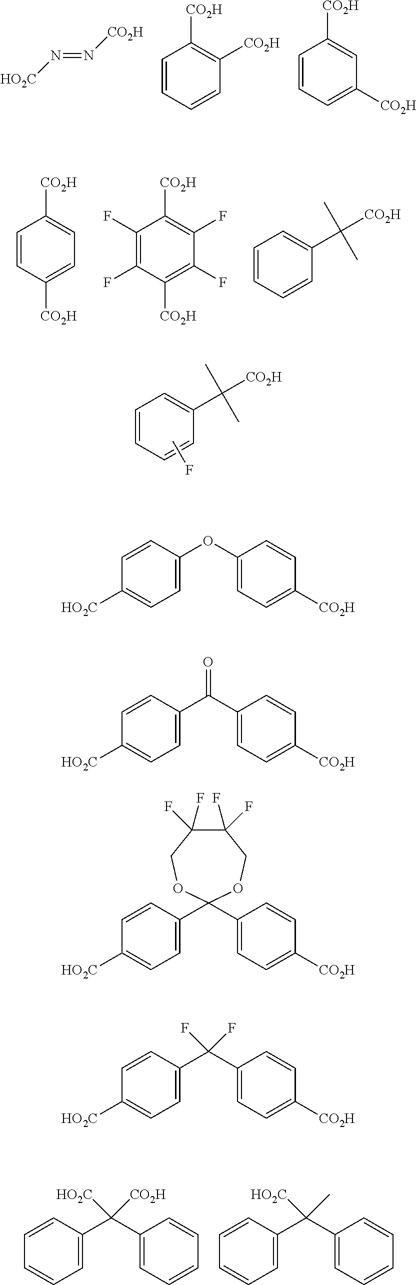

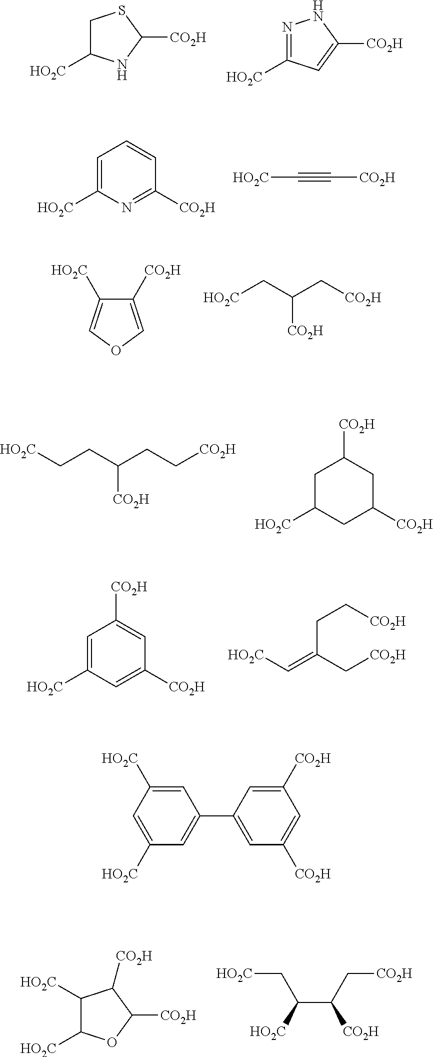

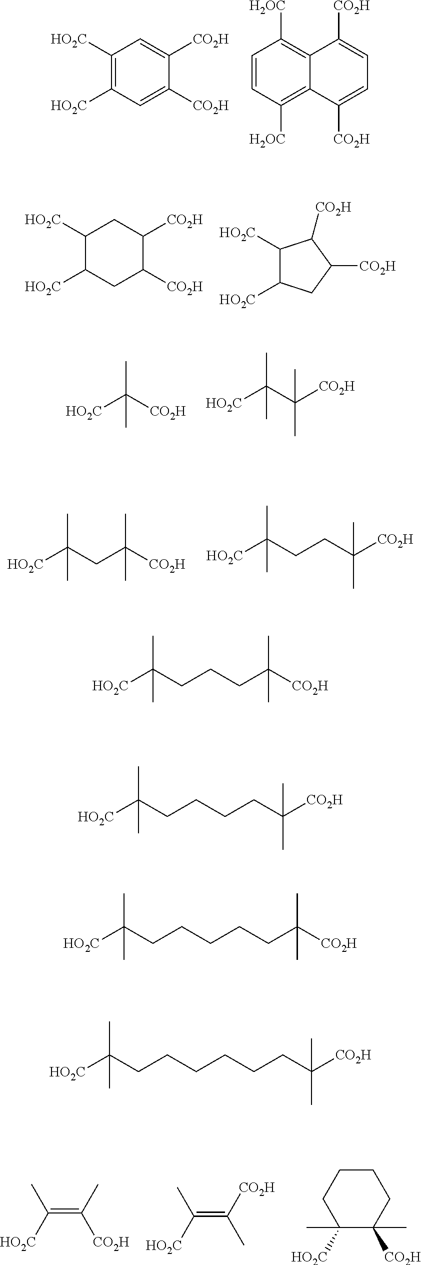

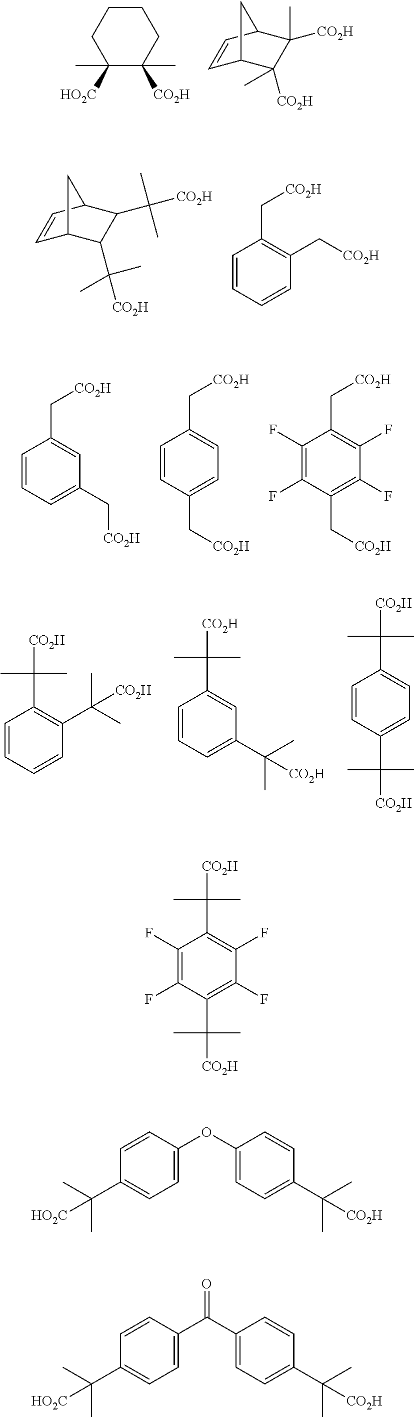

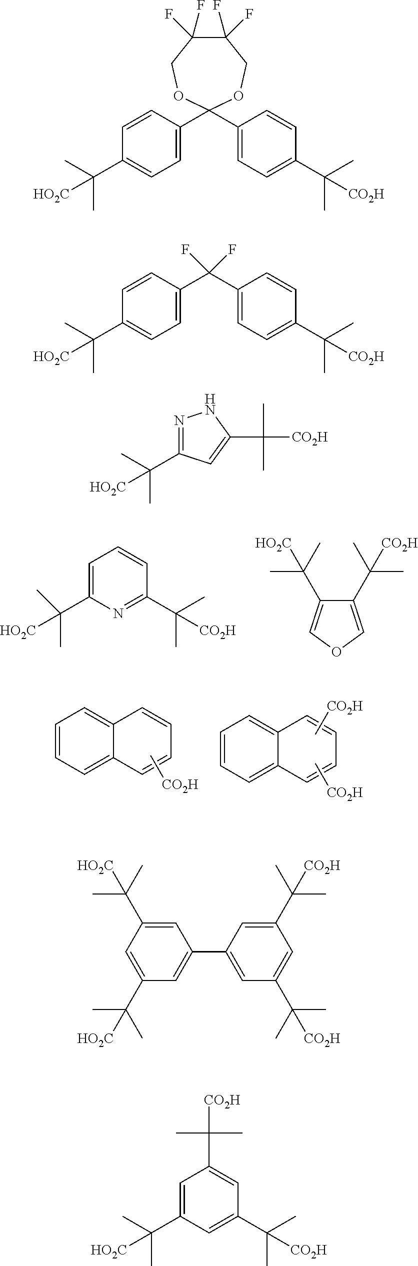

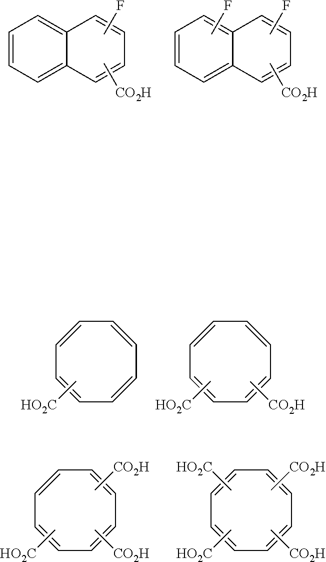

The carboxy group-containing polymer containing a repeat unit having the formula (2) may further contain a repeat unit other than the repeat unit having the formula (2) (hereinafter, also referred to as another repeat unit). The repeat unit other than the repeat unit having the formula (2) is not particularly limited, and a repeat unit is preferable that is capable of improving the solubility, in a solvent, of an insoluble polymer containing only a repeat unit having a carboxy group. The repeat unit other than the repeat unit having the formula (2) is preferably a repeat unit having a robust skeleton and a cyclic structure expected to have high etching resistance, or a repeat unit having a styrene skeleton.

Specific examples of the repeat unit other than the repeat unit having the formula (2) include, but are not limited to, those exemplified as specific examples of another repeat unit that may be contained in the hypervalent iodine-containing polymer.

In the carboxy group-containing polymer, the carboxy group-containing repeat unit and another repeat unit are preferably present in a content ratio (molar ratio) of carboxy group-containing repeat unit:another repeat unit=10:90 to 90:10, more preferably 15:85 to 85:15, and still more preferably 20:80 to 80:20.

The carboxy group-containing polymer preferably has a weight average molecular weight (Mw) of 1,000 to 500,000, and more preferably 3,000 to 100,000. In the present invention, Mw represents a value measured by gel permeation chromatography (GPC) versus polystyrene standards using tetrahydrofuran (THF) as a solvent.

If the carboxy group-containing polymer has a wide molecular weight distribution (Mw/Mn), which indicates the presence of lower and higher molecular weight polymer fractions, there is a possibility that foreign matter is left on the pattern or the pattern profile is degraded after exposure. The influences of Mw and Mw/Mn become stronger as the pattern rule becomes finer. Therefore, the carboxy group-containing polymer should preferably have a narrow dispersity (Mw/Mn) of 1.0 to 2.0 in order to provide a resist composition suitable for micropatterning to a small feature size.

Examples of the method of synthesizing the carboxy group-containing polymer include a method in which monomers corresponding to the foregoing repeat units are dissolved in an organic solvent, a radical polymerization initiator is added thereto, and the resulting mixture is heated for polymerization.

Specific examples of the organic solvent used in the polymerization reaction include anisole, toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and 7-butyrolactone (GBL). Specific examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of the polymerization initiator added is preferably 0.01 to 25 mol % per total amount of monomers to be polymerized. The reaction temperature is preferably 50 to 150° C., and more preferably 60 to 100° C. The reaction time is preferably 2 to 24 hours, and more preferably 2 to 12 hours from the viewpoint of production efficiency.

The polymerization initiator may be added to the monomer solution before supply to a reaction vessel, or an initiator solution may be prepared separately from the monomer solution and each solution may be supplied to a reaction vessel independently. Radicals generated from the initiator during waiting time may promote a polymerization reaction to generate an ultrahigh polymer. Therefore, from the viewpoint of quality control, each of the monomer solution and the initiator solution is preferably prepared and added dropwise independently. Further, a known chain transfer agent such as dodecyl mercaptan or 2-mercaptoethanol may be used in combination for adjusting the molecular weight. In this case, the amount of such a chain transfer agent added is preferably 0.01 to 20 mol % per total amount of monomers to be polymerized.

The amount of each monomer in the monomer solution is to be appropriately set, for example, so as to achieve the foregoing preferred content ratio of the repeat unit.

The carboxy group-containing compound may be used alone or in admixture.

In the resist composition of the present invention, the hypervalent iodine-containing polymer and the carboxy group-containing compound are preferably present in a content ratio such that the molar ratio of the hypervalent iodine-containing polymer to the carboxy group-containing compound (the molar ratio of the hypervalent iodine-containing repeat unit in the hypervalent iodine-containing polymer to the carboxy group-containing repeat unit in the polymer when the carboxy group-containing compound is the polymer) is 10:90 to 90:10, more preferably 20:80 to 80:20, and still more preferably 30:70 to 70:30.

### Solvent

The resist composition contains a solvent. The solvent is not particularly limited as long as the hypervalent iodine-containing polymer, the carboxy group-containing compound, and other components described below are dissolvable therein and a film can be formed from the resulting solution. The solvent is preferably an organic solvent, and examples of the organic solvent include ketones such as cyclohexanone, anisole, methyl-2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono tert-butyl ether acetate; carboxylic acids such as formic acid, acetic acid, and propionic acid, lactones such as γ-butyrolactone, and mixtures thereof.

In the resist composition of the present invention, the solvent is preferably present in such amounts that the resist composition may have a solids concentration of 0.1 to 20% by weight, more preferably 0.1 to 15% by weight, even more preferably 0.1 to 10% by weight. In the present invention, the term solids is a general term for all components in the resist composition excluding the solvent. The solvent may be used alone or in admixture.

### Other Components

The resist composition may further contain a surfactant. The surfactant is preferably a fluorine-based and/or silicon-based surfactant. Examples of such a surfactant include those described in US 2008/0248425, paragraph [0276]. Surfactants other than the fluorine-based and/or silicon-based surfactants, as described in US 2008/0248425, paragraph [0280] can also be used.

When the resist composition contains the surfactant, the surfactant is preferably present in an amount of 0.0001 to 2% by weight based on the overall solids. The surfactant may be used alone or in admixture.

The resist composition may further contain a radical scavenger. When added, the radical scavenger can control photo-reaction and adjust sensitivity during photolithography.

Examples of the radical scavenger include hindered phenols, quinones, hindered amines, and thiol compounds. Specific examples of the hindered phenols include dibutylhydroxytoluene (BHT) and 2,2′-methylenebis(4-methyl-6-tert-butylphenol). Examples of the quinones include 4-methoxyphenol (or methoquinone) and hydroquinone. Examples of the hindered amines include 2,2,6,6-tetramethylpyperidine and 2,2,6,6-tetramethylpyperidine-N-oxy radical. Examples of the thiols include dodecanethiol and hexadecanethiol.

When the resist composition contains the radical scavenger, the radical scavenger is preferably present in an amount of 0.01 to 10% by weight based on the overall solids. The radical scavenger may be used alone or in admixture.

The resist composition may further contain a crosslinking agent. By adding the crosslinking agent, the crosslinking reaction during photolithography is promoted, the glass transition point of the pattern is improved, and a pattern excellent in resolution in a thin line is obtained.

Examples of the crosslinking agent include a compound having, as a functional group, a carbon-carbon unsaturated bond such as a vinyl group, (meth)acrylate group, allyl group, alkynyl group, and aromatic ring. Specific examples of the compound having a vinyl group include chain alkenes, branched alkenes, and cyclic alkenes which may have a substituent. Examples of the compound having a (meth)acrylate group include acrylic acid, methacrylic acid, acrylic acid ester, and methacrylic acid ester which may have a substituent. Examples of the compound having an allyl group include allyl alcohol, allyl ether, allyl ester, allyl amide, allylamine, and allyl group-containing isocyanurates which may have a substituent. Examples of the compound having an alkynyl group include chain alkynes, branched alkynes, cyclic alkynes, alkynyl alcohols, alkynyl ethers, alkynyl esters, alkynyl amides, alkynyl amines, and alkynyl group-containing isocyanurates which may have a substituent. Examples of the compound having an aromatic ring include arenes, heteroarenes, styrene, stilbene, phenylacetylene, acenaphthylene, and chalcone which may have a substituent. The crosslinking agent may have only one of the functional groups described above, or may have a plurality of the functional groups. The number of the functional groups contained in the crosslinking agent is preferably 1 or more and 10 or less, and more preferably 2 or more and 8 or less.

When the resist composition contains the crosslinking agent, the crosslinking agent is preferably present in an amount of 0.01 to 50% by weight based on the overall solids. The crosslinking agent may be used alone or in admixture.

When the resist composition contains the crosslinking agent, the resist composition may further contain a photopolymerization initiator. The photopolymerization initiator can generate radicals by irradiation with high-energy radiation to promote the crosslinking of the crosslinking agent.

Specific examples of the photopolymerization initiator include benzophenone derivatives such as benzophenone, methyl O-benzoylbenzoate, 4-benzoyl-4′-methyldiphenyl ketone, dibenzyl ketone, and fluorenone; acetophenone derivatives such as 2,2′-diethoxyacetophenone, 2-hydroxy-2-methylpropiophenone, 2,2-dimethoxy-1,2-diphenylethan-1-one, 1-hydroxycyclohexyl phenyl ketone, 2-methyl-1-[4-(methylthio)phenyl]-2-morpholinopropan-1-one, 2-hydroxy-1-{4-[4-(2-hydroxy-2-methylpropionyl)-benzyl]-phenyl}-2-methylpropan-1-one, and methyl phenylglyoxylate; thioxanthone derivatives such as thioxanthone, 2-methylthioxanthone, 2-isopropylthioxanthone, 4-isopropylthioxanthone, 2-chlorothioxanthone, and diethylthioxanthone; benzyl derivatives such as benzyl, benzyldimethyl ketal, and benzyl-p-methoxyethyl acetal; benzoin derivatives such as benzoin, benzoin methyl ether, and 2-hydroxy-2-methyl-1-phenylpropane-1-one; oxime compounds such as 1-phenyl-1,2-butanedione-2-(O-methoxycarbonyl)oxime, 1-phenyl-1,2-propanedione-2-(O-methoxycarbonyl)oxime, 1-phenyl-1,2-propanedione-2-(O-ethoxycarbonyl)oxime, 1-phenyl-1,2-propanedione-2-(O-benzoyl)oxime, 1,3-diphenylpropanetrione-2-(O-ethoxycarbonyl)oxime, 1-phenyl-3-ethoxypropantrione-2-(O-benzoyl)oxime, 1,2-octanedione, 1-[4-(phenylthio)-2-(O-benzoyloxime)]ethanone, and 1-[9-ethyl-6-(2-methylbenzoyl)-9H-carbazol-3-yl]-1-(0-acetyloxime); α-hydroxyketone compounds such as 2-hydroxy-2-methyl-1-phenylpropan-1-one, 1-[4-(2-hydroxyethoxy)phenyl]-2-hydroxy-2-methyl-1-propan-1-one, and 2-hydroxy-1-{4-[4-(2-hydroxy-2-methylpropionyl)-benzyl]phenyl}-2-methylpropane; α-aminoalkylphenone compounds such as 2-benzyl-2-dimethylamino-1-(4-morpholinophenyl)-butanone-1, and 2-dimethylamino-2-(4-methylbenzyl)-1-(4-morpholin-4-yl-phenyl)butan-1-one; phosphine oxide compounds such as bis(2,4,6-trimethylbenzoyl)-phenylphosphine oxide, bis(2,6-dimethoxybenzoyl)-2,4,4-trimethyl-pentylphosphine oxide, and 2,4,6-trimethylbenzoyldiphenylphosphine oxide; and titanocene compounds such as bis(η5-2,4-cyclopentadien-1-yl)-bis(2,6-difluoro-3-(1H-pyrrol-1-yl) phenyl)titanium.

When the resist composition contains the photopolymerization initiator, the photopolymerization initiator is present in an amount of preferably 0.1 to 10% by weight, more preferably 0.1 to 5% by weight, and most preferably 0.1 to 1% by weight, based on the overall solids. When the amount is 0.1% by weight or more, a sufficient compounding effect can be obtained.

As described above, the resist composition contains the hypervalent iodine-containing polymer and the carboxy group-containing compound as principal components, but not a polymer containing an acid labile group and a photoacid generator as contained in conventional chemically amplified resist compositions. Nevertheless, in particular, the resist composition of the present invention can work such that the region thereof exposed to EB or EUV turns soluble in the developer to form a positive tone pattern or turns insoluble in the developer to form a negative tone pattern. Its mechanism is not completely clear, but is presumed as follows, for example.

The repeat unit having a hypervalent iodine structure having the formula (1) has a three-coordinate structure having an aryl group and a carboxylate ligand. When the hypervalent iodine-containing polymer containing a repeat unit is mixed with a carboxy group-containing compound, replacement of carboxylate ligands takes place as an equilibration reaction. At this time, if the original carboxylate ligands can be removed by any suitable methods, a hypervalent iodine compound having new ligands is created. For example, if poly(p-iodobenzene diacetate) as the hypervalent iodine-containing polymer is mixed with a carboxy group-containing compound, and the resulting low-boiling acetic acid is removed, then ligand exchange is completed. Here, the hypervalent iodine-containing polymer is crosslinked by the carboxy group-containing compound to form a polymer having a higher molecular weight.

The crosslinked polymer are generated during film formation. This is because even if synthesized in advance, such crosslinked polymers are insoluble in most organic solvents, so that it is impossible to prepare their solution. This is presumed to be because the hypervalent iodine compound, which is originally low in solvent solubility due to the large polarization, further deteriorates in solubility by using a carboxylic acid-containing compound as a ligand. Therefore, it is desirable that the original low-molecular carboxylic acid component is removed during film formation and a subsequent bake step to complete a ligand exchange reaction and form a resist film in the step.

In the resist film obtained from the resist composition of the present invention, the supervalent iodine-containing polymer as a principal component is decomposed by light to change the polarity, and a pattern is formed by a development step. Its mechanism is not completely clear, but is presumed as follows, for example.

The resist composition of the present invention may be either positive tone or negative tone depending on the selection of components. The positive tone resist composition contains a polymer to which a hypervalent iodine compound bonds during film formation. The polymer is decomposed with light to form a monovalent iodine compound, and at the same time, the bond between the carboxy group-containing compound and the hypervalent iodine compound is also released to reduce the molecular weight. It is presumed that as a result, the exposed region is removed by the organic solvent to form a positive tone pattern.

Meanwhile, the negative tone resist composition contains a polymer crosslinked with the hypervalent iodine compound generated during film formation. The polymer is decomposed with light to cause crosslinking or bond replacement to occur, resulting in an increase in molecular weight and polarity conversion. It is presumed that as a result, the unexposed region is removed by the alkaline aqueous solution to form a negative tone pattern.

The hypervalent iodine-containing polymer used in the present invention hardly volatilizes even under vacuum conditions during EB or EUV exposure. When a hypervalent iodine compound having a small molecular weight is used, the compound decomposed by exposure volatilizes under vacuum, the resist film causes large exposure shrinkage, and contamination of an exposure machine with volatile components and dimensional change due to shrinkage of a resist pattern occur. Therefore, the above-described problem is solved by using the hypervalent iodine compound used in the present invention. By using a hypervalent iodine-containing polymer having a large molecular weight, the glass transition point of the pattern is improved, pattern deformation is prevented to improve resolution, and etching resistance is also improved.

From the foregoing presumption, the resist composition of the present invention can be said to be a non-chemically amplified resist composition. The resist composition of the present invention does not need a polymer containing an acid labile group and a photoacid generator as used in conventional chemically amplified resist compositions. Therefore, a small size pattern can be resolved without an adverse effect (for example, image blur) due to acid diffusion.

The resist composition of the present invention is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post etching residues due to the containment of metal elements, as discussed previously. In contrast, since the resist composition of the present invention does not use metal elements, it is advantageous in defectiveness over the metal resist and eliminates the problem of solvent solubility. Further, since the resist composition of the present invention can be applied to either positive tone or negative tone, the resist composition has a wide range of use applications. In the step of forming contact holes, for example, in the metal resist as conducted in negative tone development, a reversal processing step is required after the formation of a pillar pattern, but in the positive tone resist, such a step is unnecessary. Therefore, also from the viewpoint of process simplicity, the resist composition of the present invention is regarded more useful than the metal resist composition.

JP-A 2015-180928 and JP-A 2018-95853 describe a resist composition comprising a hypervalent iodine compound as an additive and a resist composition comprising a base polymer having a hypervalent iodine compound incorporated in its framework. It is described in these patent documents that these resist compositions are successful only in improving line edge roughness. They refer nowhere to a possibility of photo-decomposition of the hypervalent iodine compound and an ability to function as a non-chemically amplified resist material. Further, according to the description regarding the compounding amount and specific examples, the hypervalent iodine compound is not a principal component in these resist compositions. It is then believed that a material capable of reducing shot noise during the EUV lithography and forming a small size pattern as the non-chemically amplified material is not conceivable from these patent documents. That is, the present invention provides a definitely novel resist composition and pattern forming process.

### Pattern Forming Process

When the resist composition of the present invention is used in the fabrication of various integrated circuits, any well-known lithography techniques are applicable. For example, the invention provides a pattern forming process comprising the steps of applying the resist composition onto a substrate or a lower layer film of a substrate on which the lower layer film is laminated to form a resist film thereon, exposing the resist film to high-energy radiation, and optionally developing the exposed resist film in a developer.

First, the resist composition of the present invention is applied onto a substrate for integrated circuit fabrication, a lower layer film of a substrate on which the lower layer film is laminated (e.g., Si, SiO₂, SiN, SiON, TiN, WSi, BPSG, SOG, or organic antireflective coating), a substrate for mask circuit fabrication, or a lower layer film of a substrate on which the lower layer film is laminated (e.g., Cr, CrO, CrON, MoSi₂, or SiO₂) by any suitable technique such as spin coating, roll coating, flow coating, dip coating, spray coating, or doctor coating. The coating is prebaked on a hot plate at a temperature of preferably 60 to 200° C. for 10 seconds to 30 minutes, more preferably at 80 to 180° C. for 30 seconds to 20 minutes to form a resist film having a thickness of 0.01 to 2 μm. The lower layer film means a film formed between a substrate and a resist film in a multilayer resist process. The lower layer film is not particularly limited, and a conventionally known film can be used.

Next the resist film is exposed to high-energy radiation. The radiation is selected from among UV, deep UV, EB, EUV, X-ray, soft X-ray, excimer laser radiation, γ-ray, and synchrotron radiation. On use of UV, deep UV, EUV, X-ray, soft X-ray, excimer laser radiation, T-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 8,000 μC/cm², more preferably about 0.5 to 5,000 μC/cm². The resist composition of the present invention is best suited in micropatterning using EB or EUV as the high-energy radiation.

If necessary, the resist film is post-exposure baked (PEB). Preferably PEB is performed on a hot plate or in an oven at 30 to 200° C. for 10 seconds to 30 minutes, more preferably at 60 to 120° C. for 30 seconds to 20 minutes.

After the exposure or PEB, the resist film is developed in a developer to form a pattern, if necessary. The organic solvent used as the developer is preferably selected from an aqueous alkali solution such as an aqueous tetramethylammonium hydroxide solution or an aqueous tetrabutylammonium hydroxide solution; and 2-octanone, 2-nonanone, 2-heptanone, 3-heptanone, 4-heptanone, 2-hexanone, 3-hexanone, diisobutyl ketone, 5-methyl-2 hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butylcyclohexyl acetate, octyl acetate, isobornyl acetate, propyl formate, butyl formate, isobutyl formate, pentyl formate, isopentyl formate, methyl valerate, methyl pentenate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 2-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole, and F-caprolactone. These developers may be used alone or in admixture of two or more.

At the end of development, the resist film is rinsed if necessary. As the rinsing liquid, a solvent which is miscible with the developer and does not dissolve the resist film is preferred. Preferred examples of the solvent to be used include alcohols having 3 to 10 carbon atoms, ether compounds having 8 to 12 carbon atoms, alkanes, alkenes, and alkynes having 6 to 12 carbon atoms, and aromatic solvents.

Rinsing is effective for preventing the resist pattern from collapse or reducing defect formation. Rinsing is not essential. By omitting rinsing, the amount of the solvent used is saved.

### EXAMPLES

Synthesis Examples, Examples, and Comparative Examples of the invention are given below by way of illustration and not by way of limitation.

In Synthesis Examples described below, monomers used for the synthesis of a polymer are identified below.

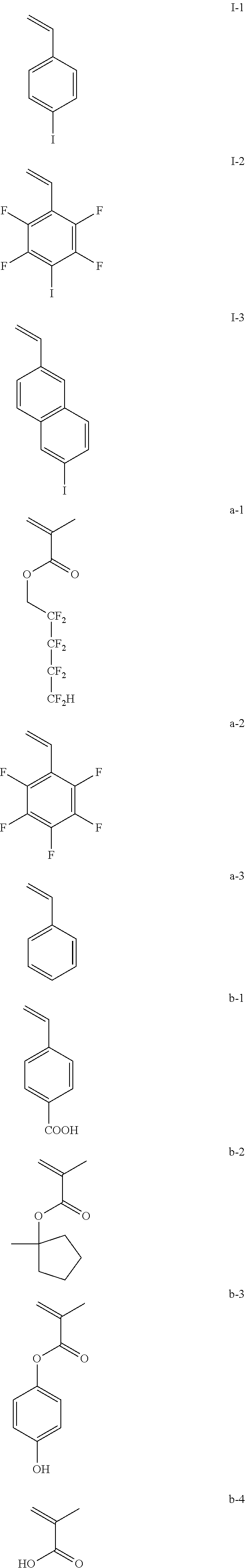

### [1] Synthesis of Iodine-Containing Polymer

### Synthesis Example 1-1

### Synthesis of Iodine-Containing Polymer PI-2

In a nitrogen atmosphere, a monomer I-1 (43 g), a monomer a-1 (57 g), V-601 (manufactured by FUJIFILM Wako Pure Chemical Corporation) (4.2 g), and MEK (160 g) were put into a flask to prepare a monomer-polymerization initiator solution. In another flask under a nitrogen atmosphere, 80 g of MEK was put and heated to 80° C. while stirred, and then the monomer-polymerization initiator solution was added dropwise over 4 hours. After completion of the dropwise addition, stir of the polymerization liquid was continued for 2 hours while the liquid temperature was maintained at 80° C., and then the polymerization liquid was cooled to room temperature. The obtained polymerization liquid was added dropwise to 4,000 g of vigorously stirred hexane, and the precipitated polymer was separated by filtration. The obtained polymer was washed twice with hexane (1200 g), and then vacuum-dried at 50° C. for 20 hours to obtain a polymer PI-2 in the form of a white powder (yield: 92 g, yield rate: 92%). The polymer PI-2 had a value of Mw of 7,000, and a value of Mw/Mn of 1.44. The value of Mw was measured by GPC versus polystyrene standards using THF as a solvent.

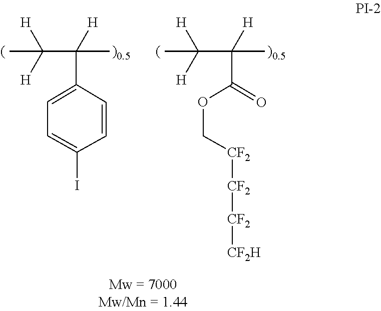 [SMILES: CCC(C)c1ccc(I)cc1 ; CCC(C)C(=O)OCC(F)(F)C(F)(F)C(F)(F)C(F)F]

### Synthesis Examples 1-2 to 1-8

### Synthesis of Hypervalent Iodine-Containing Polymers PI-1, PI-3 to PI-10

Polymers shown in Table 1 were synthesized in the same manner as in Synthesis Example 1-1 except that the kind and the compounding ratio of each monomer were changed.

TABLE 1

| Iodine- | | Incorporation | | Incorporation | | |
|---|---|---|---|---|---|---|
| containing | | ratio | | ratio | | |
| polymer | Unit 1 | (mol %) | Unit 2 | (mol %) | Mw | Mw/Mn |
| PI-1 | I-1 | 100 | — | — | 7,000 | 1.44 |
| PI-2 | I-1 | 50 | a-1 | 50 | 7,000 | 1.44 |
| PI-3 | I-1 | 50 | a-2 | 50 | 8,400 | 1.51 |
| PI-4 | I-1 | 60 | a-3 | 40 | 8,100 | 1.42 |
| PI-5 | I-2 | 60 | a-1 | 40 | 8,100 | 1.42 |
| PI-6 | I-2 | 65 | a-2 | 35 | 8,000 | 1.44 |
| PI-7 | I-2 | 50 | a-3 | 50 | 8,600 | 1.41 |
| PI-8 | I-3 | 60 | a-1 | 40 | 7,900 | 1.49 |
| PI-9 | I-3 | 65 | a-2 | 35 | 7,000 | 1.45 |
| PI-10 | I-3 | 65 | a-3 | 35 | 6,000 | 1.40 |

### [2] Synthesis of Hypervalent Iodine-Containing Polymer

### Synthesis Example 2-1

### Synthesis of Hypervalent Iodine-Containing Polymer PH-2

In a nitrogen atmosphere, a polymer PI-2 (10 g) and 100 g of acetic anhydride were mixed in a flask, and 18 g of 35% hydrogen peroxide water was added dropwise thereto at room temperature. This reaction solution was stirred at room temperature for 2 hours, then stirred at 60° C. for 5 hours, then returned to room temperature, and further stirred for 2 hours. Hexane was added to the obtained reaction solution to remove the supernatant, thereby obtaining 11.5 g of the desired polymer PH-2 as an oily substance (yield rate: 94%). The polymer PH-2 had a value of Mw of 8600, and a value of Mw/Mn of 1.44. The value of Mw was measured by GPC versus polystyrene standards using THE as a solvent.

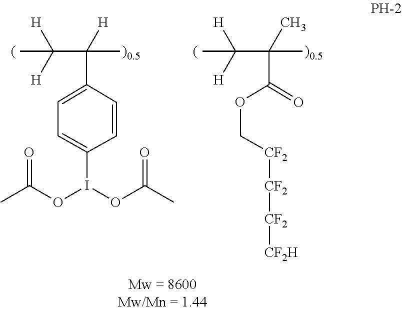 [SMILES: CCC(C)c1ccc(I(OC(C)=O)OC(C)=O)cc1 ; CCC(C)(C)C(=O)OCC(F)(F)C(F)(F)C(F)(F)C(F)F]

### Synthesis Examples 2-2 to 2-8

### Synthesis of Hypervalent Iodine-Containing Polymers PH-1, PH-3 to PH-10

Polymers shown in Table 2 were synthesized in the same manner as in Synthesis Example 2-1 except that the kind of an iodine-containing polymer used was changed.

TABLE 2

| Hypervalent iodine-containing | Iodine-containing | | |
|---|---|---|---|
| polymer | polymer | Mw | Mw/Mn |
| PH-1 | PI-1 | 10,000 | 1.44 |
| PH-2 | PI-2 | 8,600 | 1.44 |
| PH-3 | PI-3 | 11,000 | 1.51 |
| PH-4 | PI-4 | 11,000 | 1.42 |
| PH-5 | PI-5 | 10,000 | 1.42 |
| PH-6 | PI-6 | 10,000 | 1.44 |
| PH-7 | PI-7 | 11,000 | 1.41 |
| PH-8 | PI-8 | 10,000 | 1.49 |
| PH-9 | PI-9 | 11,000 | 1.45 |
| PH-10 | PI-10 | 10,000 | 1.40 |

### [3] Synthesis of Carboxy Group-Containing Polymer

### Synthesis Example 3-1

### Synthesis of Carboxy Group-Containing Polymer P-1

In a nitrogen atmosphere, a monomer b-4 (22 g), a monomer a-1 (78 g), V-601 (manufactured by FUJIFILM Wako Pure Chemical Corporation) (5.4 g), and MEK (160 g) were put into a flask to prepare a monomer-polymerization initiator solution. In another flask under a nitrogen atmosphere, 55 g of MEK was put and heated to 80° C. while stirred, and then the monomer-polymerization initiator solution was added dropwise over 4 hours. After completion of the dropwise addition, stir of the polymerization liquid was continued for 2 hours while the liquid temperature was maintained at 80° C., and then the polymerization liquid was cooled to room temperature. The obtained polymerization liquid was added dropwise to 4,000 g of vigorously stirred hexane, and the precipitated polymer was separated by filtration. The obtained polymer was washed twice with hexane (1200 g), and then vacuum-dried at 50° C. for 20 hours to obtain a polymer P-1 in the form of a white powder (yield: 100 g, yield rate: 98%). The polymer P-2 had a value of Mw of 7,000, and a value of Mw/Mn of 1.44. The value of Mw was measured by GPC versus polystyrene standards using THF as a solvent.

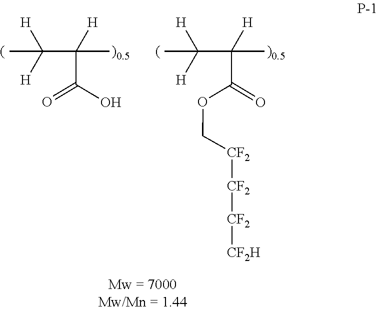

### Synthesis Examples 3-2 to 3-5

### Synthesis of Carboxy Group-Containing Polymers P-2 to P-4 and Comparative Example Polymer P-5

Polymers shown in Table 3 were synthesized in the same manner as in Synthesis Example 3-1 except that the kind and the compounding ratio of each monomer were changed.

TABLE 3

| | | Incorporation | | Incorporation | | |
|---|---|---|---|---|---|---|
| | | ratio | | ratio | | |
| Polymer | Unit 1 | (mol %) | Unit 2 | (mol %) | Mw | Mw/Mn |
| P-1 | b-4 | 50 | a-1 | 50 | 7,000 | 1.44 |
| P-2 | b-4 | 50 | a-2 | 50 | 8,400 | 1.51 |
| P-3 | b-1 | 60 | a-1 | 40 | 8,100 | 1.42 |
| P-4 | b-1 | 60 | a-2 | 40 | 8,100 | 1.42 |
| P-5 | b-2 | 60 | b-3 | 40 | 8,000 | 1.44 |

### [4] Preparation of Resist Composition

### Examples 1-1 to 1-17, Comparative Examples 1-1 to 1-4

Resist compositions (R-01 to R-17, CR-01 and CR-02) were prepared by dissolving a hypervalent iodine compound and a carboxy group-containing compound in a solvent containing 0.01% by weight of a surfactant (PF-636, manufactured by OMNOVA Solutions Inc.) in accordance with the recipe shown in Table 4, and filtering the solution through a Teflon® filter having a pore size of 0.2 μm. Separately, resist compositions (CR-03 to CR-04) were prepared by dissolving a polymer, a photoacid generator, and a sensitivity modifier in a solvent containing 0.01% by weight of a surfactant (PF-636, manufactured by OMNOVA Solutions Inc.) in accordance with the recipe shown in Table 5, and filtering the solution through a Teflon® filter having a pore size of 0.2 μm.

TABLE 4

| | | | Hypervalent | Carboxy group- | | |
|---|---|---|---|---|---|---|
| | | Resist | iodine compound | containing compound | Solvent 1 | Solvent 2 |
| | | composition | (pbw) | (pbw) | (pbw) | (pbw) |
| Example | 1-1 | R-01 | PH-1 (11) | P-1 (24) | PGMEA (800) | AcOH (200) |
| | 1-2 | R-02 | PH-2 (5) | P-1 (24) | PGMEA (800) | AcOH (200) |
| | 1-3 | R-03 | PH-3 (4) | P-1 (24) | PGMEA (800) | AcOH (200) |
| | 1-4 | R-04 | PH-4 (5) | P-1 (24) | PGMEA (800) | AcOH (200) |
| | 1-5 | R-05 | PH-5 (7) | P-1 (24) | PGMEA (800) | AcOH (200) |
| | 1-6 | R-06 | PH-6 (7) | P-1 (24) | PGMEA (800) | AcOH (200) |
| | 1-7 | R-07 | PH-7 (4) | P-1 (24) | PGMEA (800) | AcOH (200) |
| | 1-8 | R-08 | PH-8 (7) | P-1 (24) | PGMEA (800) | AcOH (200) |
| | 1-9 | R-09 | PH-9 (7) | P-1 (24) | PGMEA (800) | AcOH (200) |
| | 1-10 | R-10 | PH-10 (6) | P-1 (24) | PGMEA (800) | AcOH (200) |
| | 1-11 | R-11 | PH-2 (5) | P-2 (17) | PGMEA (800) | AcOH (200) |
| | 1-12 | R-12 | PH-2 (5) | P-3 (21) | PGMEA (800) | AcOH (200) |
| | 1-13 | R-13 | PH-2 (5) | P-4 (17) | PGMEA (800) | AcOH (200) |
| | 1-14 | R-14 | PH-2 (5) | m-1 (7) | PGMEA (800) | AcOH (200) |
| | 1-15 | R-15 | PH-2 (5) | m-2 (7) | PGMEA (800) | AcOH (200) |
| | 1-16 | R-16 | PH-2 (5) | m-3 (7) | PGMEA (800) | AcOH (200) |
| | 1-17 | R-17 | PH-2 (5) | m-4 (8) | PGMEA (800) | AcOH (200) |
| Comparative | 1-1 | CR-01 | H-1 (10) | P-1 (24) | PGMEA (800) | AcOH (200) |
| Example | 1-2 | CR-02 | H-1 (10) | P-3 (21) | PGMEA (800) | AcOH (200) |

TABLE 5

| | | | | Photoacid | Sensitivity | | |
|---|---|---|---|---|---|---|---|
| | | Resist | Polymer | generator | modifier | Solvent 1 | Solvent 2 |
| | | composition | (pbw) | (pbw) | (pbw) | (pbw) | (pbw) |
| Comparative | 1-3 | CR-03 | P-5 (80) | PAG-1 (19) | Q-1 (6) | PGMEA (1890) | GBL (210) |
| Example | 1-4 | CR-04 | P-5 (80) | PAG-1 (19) | H-1 (5) | PGMEA (1890) | GBL (210) |

In Tables 4 and 5, the hypervalent iodine compound H-1, the carboxy group-containing compounds m-1 to m-4, the photoacid generator PAG-1, the sensitivity modifier Q-1, and the solvent are identified below.

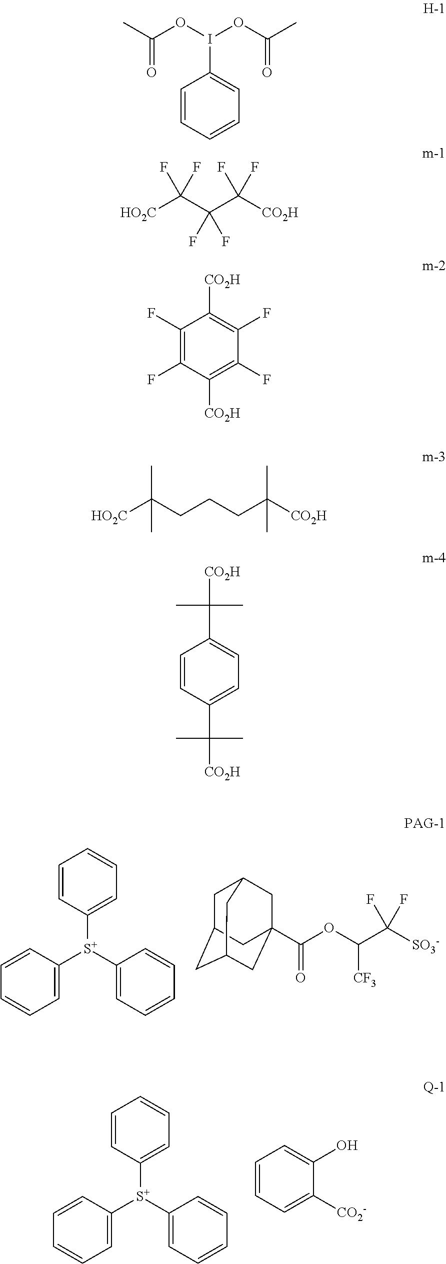

### Solvent:

PGMEA (propylene glycol monomethyl ether acetate)
AcOH (acetic acid)
GBL (γ-butyrolactone)

### [5] EUV Lithography Test (Line-and-Space Pattern)

### Examples 2-1 to 2-17 and Comparative Examples 2-1 to 2-4

Each of the resist compositions (R-01 to R-17, CR-01 to CR-04) was spin coated on a silicon substrate having a 20-nm coating of silicon-containing spin-on hard mask SHB-A940 (Shin-Etsu Chemical Co., Ltd., silicon content 43 wt %) and prebaked (PAB) on a hotplate at the temperature shown in Table 6 for 60 seconds to form a resist film of 40 nm thick. Using an EUV scanner NXE3400 (ASML, NA 0.33, σ 0.9, 900 dipole illumination), the resist film was exposed to EUV through a mask bearing a 36-nm 1:1 line-and-space (LS) pattern. The resist film was baked (PEB) on a hotplate at the temperature shown in Table 6 for 60 seconds and developed in the developer shown in Table 6 for 30 seconds to form a LS pattern having a space width of 18 nm and a pitch of 36 nm.

The obtained resist pattern was evaluated as follows. Table 6 shows the results.

### [Evaluation of Sensitivity]

The LS pattern was observed under CD-SEM (CG-6300, Hitachi High-Tech Corporation), and the optimum dose (Eop, mJ/cm²) which provided an LS pattern with a space width of 18 nm and a pitch of 36 nm was determined and reported as sensitivity.

### [Evaluation of LWR]

An LS pattern was formed by exposure in the optimum dose (Eop). The space width was measured under CD-SEM (CG-6300, Hitachi High-Tech Corporation) at longitudinally spaced apart 10 points, from which a 3-fold value (3σ) of the standard deviation (σ) was determined and reported as LWR. A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined under CD-SEM (CG-6300, Hitachi High-Tech Corporation) and reported as maximum resolution (nm). A smaller value indicates a pattern having a better maximum resolution and smaller feature size.

TABLE 6

| | | | | | | | | Maximum |
|---|---|---|---|---|---|---|---|---|
| | | Resist | PAB/PEB | | Pattern | Eop | LWR | resolution |
| | | composition | (° C.) | Developer | tone | (mJ/cm²) | (nm) | (nm) |
| Example | 2-1 | R-01 | 110/90 | nBA | positive | 50 | 3.2 | 13 |
| | 2-2 | R-02 | 110/90 | nBA | positive | 40 | 3.5 | 13 |
| | 2-3 | R-03 | 110/90 | nBA | positive | 45 | 3.0 | 13 |
| | 2-4 | R-04 | 110/90 | nBA | positive | 45 | 3.2 | 13 |
| | 2-5 | R-05 | 110/90 | nBA | positive | 47 | 3.1 | 13 |
| | 2-6 | R-06 | 110/90 | nBA | positive | 43 | 3.0 | 13 |
| | 2-7 | R-07 | 110/90 | nBA | positive | 45 | 3.2 | 13 |
| | 2-8 | R-08 | 110/90 | nBA | positive | 47 | 3.1 | 15 |
| | 2-9 | R-09 | 110/90 | nBA | positive | 40 | 3.3 | 14 |
| | 2-10 | R-10 | 110/90 | nBA | positive | 45 | 3.5 | 14 |
| | 2-11 | R-11 | 110/90 | nBA | positive | 45 | 3.3 | 14 |
| | 2-12 | R-12 | 110/90 | TMAH | negative | 45 | 3.3 | 15 |
| | 2-13 | R-13 | 110/90 | TMAH | negative | 40 | 3.3 | 14 |
| | 2-14 | R-14 | 110/90 | TMAH | negative | 45 | 3.4 | 15 |
| | 2-15 | R-15 | 110/90 | TMAH | negative | 45 | 3.2 | 15 |
| | 2-16 | R-16 | 110/90 | nBA | positive | 50 | 3.4 | 15 |
| | 2-17 | R-17 | 110/90 | nBA | positive | 40 | 3.6 | 15 |
| Comparative | 2-1 | CR-01 | 110/90 | nBA | positive | 44 | 4.3 | 16 |
| Example | 2-2 | CR-02 | 105/90 | TMAH | negative | 48 | 4.2 | 16 |
| | 2-3 | CR-03 | 105/90 | TMAH | positive | 85 | 4.4 | 18 |
| | 2-4 | CR-04 | 105/90 | TMAH | positive | 85 | 5.0 | 18 |

Developer:
nBA (butyl acetate)
TMAH (2.38 wt % aqueous tetramethylammonium hydroxide solution)

From the results shown in Table 6, it was found that both positive tone and negative tone patterns can be formed by the developer to be used. The resist composition of the present invention had more excellent resolution and LWR than those of Comparative Examples 2-1 and 2-2 using the hypervalent iodine compound having a small molecular weight. Also, the resist composition of the present invention had more excellent sensitivity, resolution and LWR than those of Comparative Examples 2-3 and 2-4 which were chemically amplified resist compositions using an acid catalytic reaction. Therefore, it was found that the resist composition of the present invention has excellent resolution in LS pattern formation due to EUV exposure.

### [6] EUV Lithography Test (Contact Hole Pattern)

### Examples 3-1 to 3-17, Comparative Examples 3-1 to 3-4

Each of the resist compositions (R-01 to R-17, CR-01 to CR-04) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 7 for 60 seconds to form a resist film of 50 nm thick. Using an EUV scanner NXE3400 (ASML, NA 0.33, σ 0.9/0.6, quadrupole illumination), the resist film was exposed to EUV through a mask bearing a hole pattern with a pitch of 64 nm+20% bias (on-wafer size). After exposure, the resist film was baked (PEB) on a hotplate at the temperature shown in Table 7 for 60 seconds and developed in the developer shown in Table 7 for 30 seconds to form a hole pattern having a size of 32 nm.

The obtained resist pattern was evaluated as follows. Table 7 shows the results.

### [Evaluation of Sensitivity]

The contact hole pattern was observed under CD-SEM (CG-6300, Hitachi High-Tech Corporation), and the optimum dose (Eop, mJ/cm²) which provided a hole pattern with a size of 22 nm was determined and reported as sensitivity.

### [Evaluation of CDU]

The size of 50 holes which were printed at Eop was measured, from which a 3-fold value (3σ) of the standard deviation (α) was computed and reported as CDU. A smaller value of CDU indicates a hole pattern with more uniform hole diameter.

### [Evaluation of Maximum Resolution]

A hole pattern was formed while reducing the exposure dose little by little from the optimum dose (Eop). The hole diameter (nm) which could be resolved was determined under CD-SEM (CG-6300, Hitachi High-Tech Corporation) and reported as maximum resolution. A smaller value indicates a pattern having a better maximum resolution and smaller hole diameter.

TABLE 7

| | | | | | | | | Maximum |
|---|---|---|---|---|---|---|---|---|
| | | Resist | PAB/PEB | | Pattern | Eop | CDU | resolution |
| | | composition | (° C.) | Developer | tone | (mJ/cm²) | (nm) | (nm) |
| Example | 3-1 | R-01 | 110/90 | nBA | positive | 40 | 2.2 | 25 |
| | 3-2 | R-02 | 110/90 | nBA | positive | 30 | 2.7 | 25 |
| | 3-3 | R-03 | 110/90 | nBA | positive | 35 | 2.1 | 24 |
| | 3-4 | R-04 | 110/90 | nBA | positive | 36 | 2.1 | 24 |
| | 3-5 | R-05 | 110/90 | nBA | positive | 36 | 2.3 | 25 |
| | 3-6 | R-06 | 110/90 | nBA | positive | 33 | 2.1 | 24 |
| | 3-7 | R-07 | 110/90 | nBA | positive | 35 | 2.2 | 25 |
| | 3-8 | R-08 | 110/90 | nBA | positive | 36 | 2.3 | 25 |
| | 3-9 | R-09 | 110/90 | nBA | positive | 32 | 2.4 | 26 |
| | 3-10 | R-10 | 110/90 | nBA | positive | 34 | 2.5 | 26 |
| | 3-11 | R-11 | 110/90 | nBA | positive | 34 | 2.4 | 26 |
| | 3-12 | R-12 | 110/90 | TMAH | negative | 41 | 2.9 | 28 |
| | 3-13 | R-13 | 110/90 | TMAH | negative | 31 | 2.4 | 26 |
| | 3-14 | R-14 | 110/90 | TMAH | negative | 37 | 2.4 | 26 |
| | 3-15 | R-15 | 110/90 | TMAH | negative | 37 | 2.2 | 26 |
| | 3-16 | R-16 | 110/90 | nBA | positive | 40 | 2.4 | 29 |
| | 3-17 | R-17 | 110/90 | nBA | positive | 32 | 2.9 | 29 |
| Comparative | 3-1 | CR-01 | 110/90 | nBA | positive | 35 | 3.8 | 30 |
| Example | 3-2 | CR-02 | 105/90 | TMAH | negative | 40 | 3.7 | 30 |
| | 3-3 | CR-03 | 105/90 | TMAH | positive | 50 | 4.2 | 32 |
| | 3-4 | CR-04 | 105/90 | TMAH | positive | 50 | 4.2 | 32 |

From the results shown in Table 7, it was found that both positive tone and negative tone patterns can be formed by selecting the developer to be used. The resist composition of the present invention had more excellent resolution and CDU than those of Comparative Examples 3-1 and 3-2 using the hypervalent iodine compound having a small molecular weight. Also, the resist composition of the present invention had more excellent sensitivity, resolution and CDU than those of Comparative Examples 3-3 and 3-4 which were chemically amplified resist compositions using an acid catalytic reaction. Therefore, it was found that the resist composition of the present invention has excellent resolution in contact hole pattern formation due to EUV exposure.

Japanese Patent Application No. 2024-109200 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a polymer containing a repeat unit having a hypervalent iodine structure having the formula (1), a carboxy group-containing compound, and a solvent: 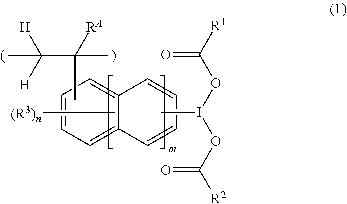
wherein m is 0 or 1, n is 0, 1, 2, 3, or 4 when m is 0, and is 0, 1, 2, 3, 4, 5, or 6 when m is 1,
R^{A} is a hydrogen atom, halogen atom, methyl group, or trifluoromethyl group,
R¹ and R² are each independently a halogen atom or a C₁-C₁₀ hydrocarbyl group which may contain a heteroatom, and R¹ and R² may bond together to form a ring with the carbon atoms to which they are attached and the intervenient atoms, and
R³ is a halogen atom or a C₁-C₂₀ hydrocarbyl group which may contain a heteroatom.

2. The resist composition according to claim 1, wherein the carboxy group-containing compound is a polymer containing a repeat unit having the formula (2) or a compound having the formula (3): 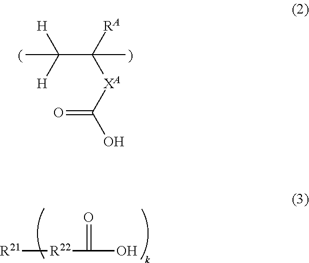
wherein R^{A} is a hydrogen atom, halogen atom, methyl group, or trifluoromethyl group,
X^{A} is a single bond, phenylene group, naphthylene group, or *—C(═O)—O—X^{A1}—, wherein X^{A1} is a C₁-C₁₀ saturated hydrocarbylene group, phenylene group, or naphthylene group, the saturated hydrocarbylene group may contain a hydroxy group, ether bond, ester bond, or lactone ring, and * designates a valence bond to a carbon atom in a main chain,
k is 1, 2, 3, or 4,
R¹¹ is a C₁-C₄₀ k-valent hydrocarbon group or C₂-C₄₀ k-valent heterocyclic group, when k is 2, R¹¹ may be an ether bond, carbonyl group, azo group, thioether bond, carbonate bond, carbamate bond, sulfinyl group, or sulfonyl group, some or all of the hydrogen atoms in the k-valent hydrocarbon group or k-valent heterocyclic group may be substituted by a group containing a heteroatom, and some constituent —CH₂— in the k-valent hydrocarbon group may be substituted by a group containing a heteroatom, and
R¹² is a single bond or a C₁-C₁₀ hydrocarbylene group, some or all of the hydrogen atoms in the hydrocarbylene group may be substituted by a group containing a heteroatom, some constituent —CH₂— in the hydrocarbylene group may be substituted by a group containing a heteroatom, and when k is 2, 3, or 4, a plurality of R¹² may be the same or different.

3. A laminate comprising a substrate and a resist film obtained from the resist composition according to claim 1 on the substrate.

4. The laminate according to claim 3, further comprising a lower layer film between the substrate and the resist film.

5. The laminate according to claim 3, wherein the resist film is formed by ligand exchange between the hypervalent iodine compound and the carboxy group-containing compound.

6. A pattern forming process comprising the steps of applying the resist composition according to claim 1 onto a substrate or a lower layer film of a substrate on which the lower layer film is laminated to form a resist film thereon, exposing the resist film to high-energy radiation, and developing the exposed resist film in a developer.
